(19) United States
(12) Patent Application Publication
(10) Pub. No.: US 2018/0257937 A1
(43) Pub. Date: Sep. 13, 2018

(54) Thermoelectric Materials Employing Cr-Doped N-Type and PbSe and PbTe1-xSex and Methods of Manufacturing

(71) Applicant: University of Houston System, Houston, TX (US)

(72) Inventors: Zhifeng Ren, Pearland, TX (US); Qian Zhang, Houston, TX (US); Eyob Kebede Chere, Houston, TX (US)

(73) Assignee: University of Houston System, Houston, TX (US)

(21) Appl. No.: 15/534,271

(22) PCT Filed: Dec. 10, 2015
(86) PCT No.: PCT/US2015/065124

§ 371 Date: Jun. 8, 2017

Related U.S. Application Data
(60) Provisional application No. 62/090,911, filed on Dec. 12, 2014.

(51) Int. Cl. C01B 19/00; H01L 35/16; C01G 21/00

(52) U.S. Cl. CPC C01B 19/002; H01L 35/16; C01G 21/006; C01P 2006/40; C01P 2004/03; C01P 2004/61; C01P 2002/72

(57) ABSTRACT

Systems and methods discussed herein relate to Pb—Se based thermoelectric materials for use in thermoelectric applications, the thermoelectric materials may comprise one or more dopants and are ball-milled into a powder and hot-pressed to form pressed components. The pressed components comprise improved room temperature properties, including a ZT above about 0.5 from about 300 K to about 780 K, which leads to improved device efficiency and overall function.

### CROSS-REFERENCE TO RELATED APPLICATIONS

This application is a 35 U.S.C. § 371 national stage application of PCT/US2015/065124 filed Dec. 10, 2015, and entitled “Thermoelectric Materials Employing Cr-Doped N-Type and PbSe and PbTe₁₋ₓSeₓ and Methods of Manufacturing,” which claims priority to U.S. Provisional Application No. 62/090,911, entitled “Thermoelectric Materials Employing Cr-Doped N-Type and PbSe and PbTe₁₋ₓSeₓ and Methods of Manufacturing,” filed Dec. 12, 2014, each of these applications being incorporated herein by reference in its entirety for all purposes.

### STATEMENT REGARDING FEDERALLY SPONSORED RESEARCH OR DEVELOPMENT

This work is supported by “Solid State Solar Thermal Energy Conversion Center (S³TEC)”, an Energy Frontier Research Center funded by the U.S. Department of Energy, Office of Science, Office of Basic Energy Science under award number DE-SC0001299.

### BACKGROUND

### Field of the Disclosure

The disclosure relates generally to the manufacture of thermoelectric composites. More particularly, the disclosure relates to the manufacture of thermoelectric composites useful in power generation, electronics, and semiconductors technologies.

### Background of the Technology

Materials exhibiting thermoelectric behavior may also be referred to as those exhibiting a thermoelectric effect where a temperature difference creates an electric potential (converting temperature to current), or when an electric potential creates a temperature difference. Materials exhibiting thermoelectric behavior within specific temperature ranges may be desirable for applications such as power generation, power efficiency in electronics, and semiconductors.

### BRIEF SUMMARY OF THE DISCLOSURE

In an embodiment, a thermoelectric device comprising: a thermoelectric material comprising: lead (Pb); selenium (Se); and at least one other component A according to the formula Pb₁₋ₓAₓSe.

In an embodiment, a method of fabricating a thermoelectric material comprising: hot-pressing a milled powder comprising lead (Pb), selenium (Se), tellurium (Te), and a dopant (A) according to the formula according to the formula AₓPb₁₋ₓTe_{1-y}Se_{y} to form a thermoelectric material, wherein the thermoelectric material comprises a ZT above about 0.5 from about 300 K to about 780 K.

In an embodiment, an thermoelectric device comprising: a thermoelectric material comprising: lead (Pb); tellurium (Te); selenium (Se); and a dopant A, according to the formula AₓPb₁₋ₓTe_{1-y}Se_{y}.

### BRIEF DESCRIPTION OF THE DRAWINGS

For a detailed description of the exemplary embodiments disclosed herein, reference will now be made to the accompanying drawings in which:

FIG. 1 illustrates the x-ray diffraction pattern of single phase Pb₁₋ₓCrₓSe doped with varying Cr concentrations fabricated according to certain embodiments of the present disclosure.

FIGS. 2A-2F illustrates the temperature dependence of thermoelectric properties for the materials fabricated according to embodiments of the present disclosure.

FIG. 3 illustrates the temperature dependence of thermoelectric properties for the materials according to certain embodiments of the present disclosure.

FIGS. 4A-4F illustrate the temperature dependence of properties of thermoelectric materials fabricated according to certain embodiments of the present disclosure.

FIG. 5 illustrates ZT values for thermoelectric materials fabricated according to certain embodiments of the present disclosure.

FIG. 6 illustrates the room temperature Pisarenko relations for the thermoelectric materials fabricated according to embodiments of the present disclosure.

FIG. 7 illustrates the room temperature relationships of properties for thermoelectric materials fabricated according to embodiments of the present disclosure.

FIG. 8 illustrates the temperature dependence of device efficiency for thermoelectric materials fabricated according to certain embodiments of the present disclosure as compared to other materials.

FIGS. 9A and 9B illustrate average ZT values for the thermoelectric materials fabricated according to certain embodiments of the present disclosure.

FIGS. 10A-10F illustrate temperature-dependent thermoelectric properties of CrₓPb₁₋ₓTe manufactured according to certain embodiments of the present disclosure.

FIG. 11 illustrates the specific heat of thermoelectric materials fabricated according to certain embodiments of the present disclosure with varying concentrations of Cr, Pb, Te, and Se.

FIGS. 12A-12F illustrate temperature-dependent thermoelectric properties for thermoelectric materials fabricated according to certain embodiments of the present disclosure.

FIGS. 13A-13F illustrate temperature-dependent thermoelectric properties for thermoelectric materials fabricated according to certain embodiments of the present disclosure.

FIGS. 14A-14D are SEM images for varying thermoelectric compositions fabricated according to embodiments of the present disclosure.

FIGS. 15A-15F illustrate the temperature dependence of properties of thermoelectric materials fabricated according to certain embodiments of the present disclosure.

FIGS. 16A-16F illustrate temperature-dependent thermoelectric properties of thermoelectric materials fabricated according to certain embodiments of the present disclosure.

FIG. 17 is a graph of a plurality of Pisarenko plots of thermoelectric materials fabricated according to certain embodiments of the present disclosure.

FIG. 18A illustrates the Se concentration dependence of the room temperature ZT and FIG. 18B illustrates the Se concentration dependence on the peak ZT for CrₓPb₁₋ₓTe_{1-y} Se_{y}.

FIG. 19 illustrates the temperature dependence of the calculated leg efficiencies of thermoelectric materials fabricated according to certain embodiments of the present disclosure as compared to reference materials.

FIGS. 20A-20D are images of Pb_{0.995}Cr_{0.005}Se samples fabricated according to certain embodiments of the present disclosure.

FIG. 21 is a flow chart of a method of fabricating thermoelectric materials and devices according to embodiments of the present disclosure.

### DETAILED DESCRIPTION OF THE DISCLOSED EXEMPLARY EMBODIMENTS

The following discussion is directed to various exemplary embodiments. However, one of ordinary skill in the art will understand that the examples disclosed herein have broad application, and that the discussion of any embodiment is meant only to be exemplary of that embodiment, and not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

In the following discussion and in the claims, the terms “including” and “comprising” are used in an open-ended fashion, and thus should be interpreted to mean “including, but not limited to . . . .” Also, the term “couple” or “couples” is intended to mean either an indirect or direct connection.

Thermoelectric (TE) materials are useful for power generation and/or cooling applications because of the electric voltage that develops when a temperature differential is created across the material. TE cooling systems operate on the principal that a loop (circuit) of at least two dissimilar materials can pass current, absorbing heat at one end of the junction between the materials and releasing heat at the other end of the junction, and TE power generators enable the direct conversion from heat to electricity. As such, TE materials may be fabricated so that, when heat is applied to a portion of the TE material, the electrons migrate from the hot end towards a “cold” end, e.g., a portion of the TE material where heat is not being applied. The electrical current created when the electrons migrate may be harnessed for power, and the amount of electrical current (and resultant power generated) increases with an increasing temperature difference from the hot side of the TE material to the cold side. However, when a TE material is heated up, if it is heated for a long enough time period, held at a temperature over a time period, and/or heated to a high enough temperature, the cold side may actually heat up, so the thermoelectric devices in which the TE materials are employed may also use various methods to pull heat away from the cold side.

In an embodiment, materials for thermoelectric generators are fabricated to possess high dimensionless figure of merit ZT=[S²σ/(□ₑ+□_{L})]T, where S, σ, □ₑ, □_{L}, and T are the Seebeck coefficient, electrical conductivity, electronic thermal conductivity, lattice thermal conductivity, and absolute temperature, respectively. The thermoelectric effect is a combination of phenomenon including the Seebeck effect, Peltier effect, and Thomson effect. The Seebeck coefficient is associated with the Seebeck effect, which is the name of the effect observed when an electromagnetic effect is created when a structure (loop) is heated on one side. The Peltier effect is the term used to explain heating or cooling at a junction between two different TE materials when a current is generated in a circuit or other loop comprising the two different TE materials. The Thomson effect occurs when a Seebeck coefficient is not constant at a temperature (depending upon the TE material), so when an electric current is passed through a circuit of a single TE material that has a temperature gradient along its length, heat may be absorbed, and the temperature difference may be redistributed along the length when the current is applied. Thus, higher ZT values for TE materials across a variety of temperature ranges may continue to become increasingly valuable for applications at least across the fields of TE power generation and cooling. Thermoelectric power generation and the related efficacy refers to the use of a thermal gradient formed between conductors that generates a voltage. The temperature gradient formed results in a heat flow, and some of the heat generated associated with the head flow may not be converted into voltage. The Seebeck coefficient may be employed to determine the effectiveness of a material for thermoelectric applications including cooling or power generation. In order to develop more thermoelectrically efficient materials, it may be desirable to fabricate materials with a high Seebeck coefficient and a high power factor, which is the ability of a material to produce electric power. “Enhancement of Thermoelectric Performance of n-type PbSe by Cr Doping with Optimized Carrier Concentration,” published on Jan. 7, 2015, and “Enhancement of Thermoelectric Performance in n-type PbTe_{1-y}Se_{y} by Cr Doping,” published on Feb. 26, 2015 are incorporated herein in their entireties by reference.

PbSe-Based Thermoelectric Materials

In an embodiment, titanium (Ti), vanadium (V), chromium (Cr), niobium (Nb), and molybdenum (Mo) were employed as dopants in n-type PbSe thermoelectric legs. The dopants were found to be effective in increasing the Seebeck coefficient and power factor of n-type PbSe at temperature below about 500 K. A higher Seebeck coefficients and power factor may be due to high Hall mobility of about 1000 cm² V⁻¹s⁻¹ at lower carrier concentration. Even though the highest room temperature power factor of about 3.3×10⁻³W m⁻¹K⁻² is found in 1 at. % Mo-doped PbSe, the highest ZT is achieved in Cr-doped PbSe. As used herein, the term “room temperature” may be used to describe a temperature from about 290K to about 315K. Combined with the lower thermal conductivity, the ZT of undoped PbSe was improved to ˜0.4 at room temperature and peak ZTs of about 1.0 were observed at about 573 K for Pb_{0.9925}Cr_{0.0075}Se and about 673 K for Pb_{0.995}Cr_{0.005}Se. The calculated device efficiency of Pb_{0.995}Cr_{0.005}Se is as high as about 12.5% with a cold side measuring at about 300 K and a hot side measuring at about 873 K.

Lead chalcogenide thermoelectric (TE) materials may be employed in thermoelectric applications including power generation and cooling due at least in part to their high maximum dimensionless figures of merit ZT=[S² σ/(κ_{L}+κₑ)]T, where S is the Seebeck coefficient, σ the electrical conductivity, κ_{L} the lattice thermal conductivity, κₑ the electronic thermal conductivity, and T the absolute temperature. However, a high TE device efficiency (η) may depend on the high average ZT of the TE material over the temperature range, which may be expressed as

ηₘₐₓ=[(T_{H}−T_{C})/T_{H}][(1+ZT_{average})^{1/2}−1]/[(1+ZT_{average})^{1/2}+T_{C}/T_{H}],

In this example, T_{H} is the temperature at the hot junction and T_{C} the temperature at the cold junction. Combining, in series, different materials with different peak ZT temperatures may boost the TE device efficiency. However, these components may also suffer from the added complexity of bonding, interfacial mass diffusion, and thermal expansion mismatch due to the combination of materials with differing peak ZT temperatures. Therefore, in some embodiments, it may be preferable to use a single material to span the temperature range of operation.

As discussed herein, through the combination of nanostructures and complex band structures, an increased average ZT was obtained in Na-doped p-type PbTe/Ag₂Te (from about 300K to about 750 K) as compared with pure Na-doped PbTe and La-doped n-type PbTe/Ag₂Te. In an embodiment, an increase in the average ZT was also achieved in Na-doped Pb_{0.97}Mg_{0.03}Te (from about 300K to about 750 K) due to the stabilization of the optimal carrier concentration. In some embodiments, undoped PbSe may be attractive as compared to the other compounds as it is cheaper, but its average ZT may not be as high as desired for some higher temperature applications.

Discussed herein are fabrications of and methods of fabrication of different doped n-type PbSe (Ti-, V-, Cr-, Nb- and Mo-doped PbSe) with enhanced power factors and ZTs (below 600 K), especially for Cr-doped PbSe, which also has a peak ZT>1, that allow for device efficiency of about 12.5% for a cold side of about 300 K and a hot side of about 873 K for Pb_{0.995}Cr_{0.005}Se.

Thermoelectric Material Fabrication

A plurality of n-type PbSe samples were prepared with different doping elements Pb₁₋ₓAₓSe (A: Ti, V, Cr, Nb, and Mo, x≤0.05) by melting, hand milling or ball milling, and hot pressing. The raw materials with nominal compositions were sealed in the carbon coated quartz tube and slowly (200° C./h) raised to 1100° C. and kept for 6 h, then slowly (200° C./h) cooled to 650° C. and stayed at that temperature for 50 h, finally slowly (200° C./h) cooled to room temperature. The obtained ingots were cleaned and hand milled in a glove box. The powder was loaded into the half-inch die and hot pressed by direct current hot press (dc-HP) at 600° C. for 2 min under pressure of 80 MPa. In some embodiments, the hot-pressing parameters may vary, and temperatures from about 300° C. to about 600° C. may be employed. X-ray diffraction spectra analysis was conducted on a PANalytical multipurpose diffractometer with an X'celerator detector (PANalytical X'Pert Pro). The microstructures were investigated by a scanning electron microscope (SEM, JEOL 6330F) and a high resolution transmission electron microscope (HRTEM, JEOL 2100F). The chemical composition was analyzed on an energy-dispersive X-ray (EDX) spectrometer attached to TEM. The electrical resistivity (ρ) and Seebeck coefficient (S) were simultaneously measured on a commercial system (ULVAC ZEM-3). The thermal conductivity κ was calculated using κ=DαCₚ, where D is volumetric density determined by the Archimedes method, α the thermal diffusivity obtained on a laser flash apparatus (Netzsch LFA 457), and Cₚ the specific heat measured on a differential scanning calorimetry thermal analyzer (Netzsch DSC 404 C). The Hall Coefficient R_{H} at room temperature was measured using a PPMS (Quantum Design Physical Properties Measurement System). The Hall carrier concentration n_{H} and Hall mobility μ_{H} were calculated using n_{H}=1/(eR_{H}) and μ_{H}=σR_{H}, respectively. The uncertainty for the electrical conductivity is 3%, the Seebeck coefficient 5%, the thermal conductivity 7% (comprising uncertainties of 4% for the thermal diffusivity, 5% for the specific heat, and 3% for the density), so the combined uncertainty for the power factor is 10% and that for ZT value is 12%. Error bars were not used in the figures to increase the readability of the curves.

Material Characterization

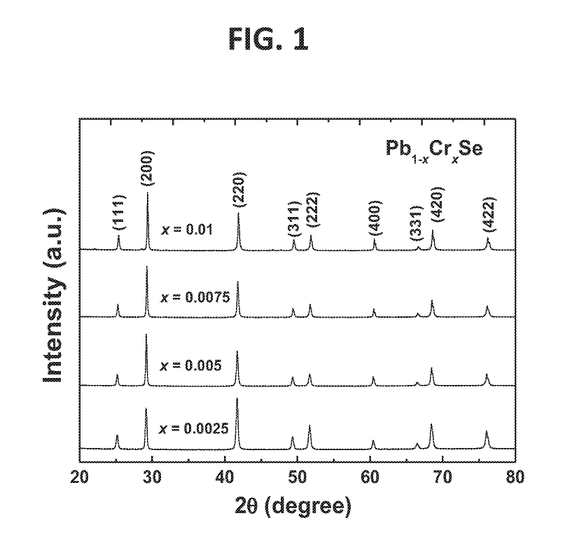

FIG. 1 illustrates the x-ray diffraction pattern of single phase Pb₁₋ₓCrₓSe doped with varying Cr concentrations fabricated according to certain embodiments of the present disclosure. Single phase Pb₁₋ₓCrₓSe was obtained with different Cr doping concentrations (x=0.0025, 0.005, 0.0075, and 0.01), which is indexed to the face-centered structure (space group Fm3̅m). Due to the large difference between the ionic radius of Pb²⁺ (1.20 Å) and Cr³⁺ (0.52 Å), all peaks shift right with increasing x. Even though secondary phases Cr_{3+□}Te₄ and Cr₂Te₃ were observed when PbTe was doped with more than 0.4 at. % Cr, no impurity formed in Cr-doped PbSe even up to 1 at. %.

Conventionally, lead chalcogenides may encounter hot side temperatures at about 673 K to about 873 K. In some embodiments, (Bi₁₋ₓSbₓ)₂(Te_{1-y}Se_{y})₃ may be employed for applications over a comparatively temperature range from about 300 K to about 473 K. Therefore, a combination of (Bi₁₋ₓSbₓ)₂(Te_{1-y}Se_{y})₃ with mid to high temperature TE materials may yield a higher device efficiency across a wider temperature range than either material alone. Using the methods and systems disclosed herein, PbSe-based materials were fabricated to exhibit TE properties that are comparable to those in Bi₂Te_{2.7}Se_{0.3} from about 300 K to about 473 K when Cr was doped into PbSe to enable higher average ZT across a large temperature range (from about 300K to about 873K).

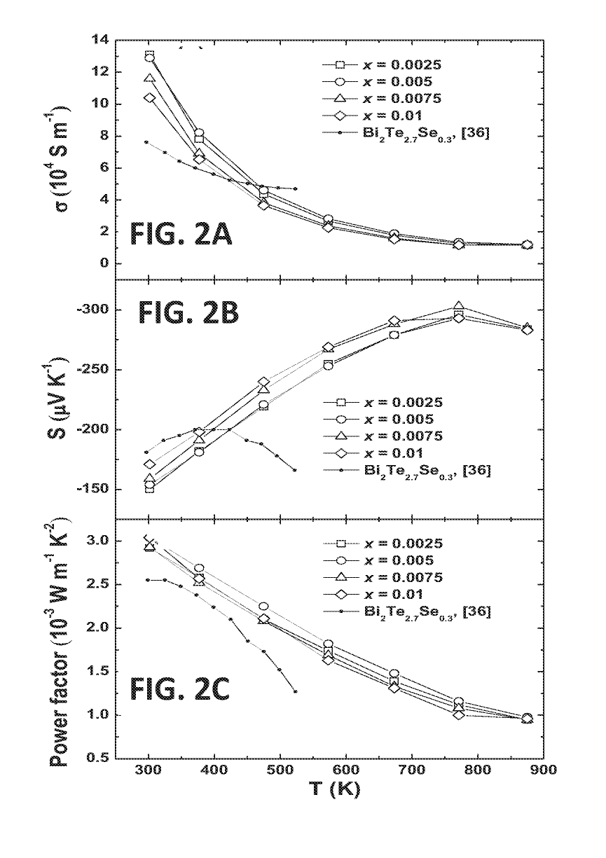

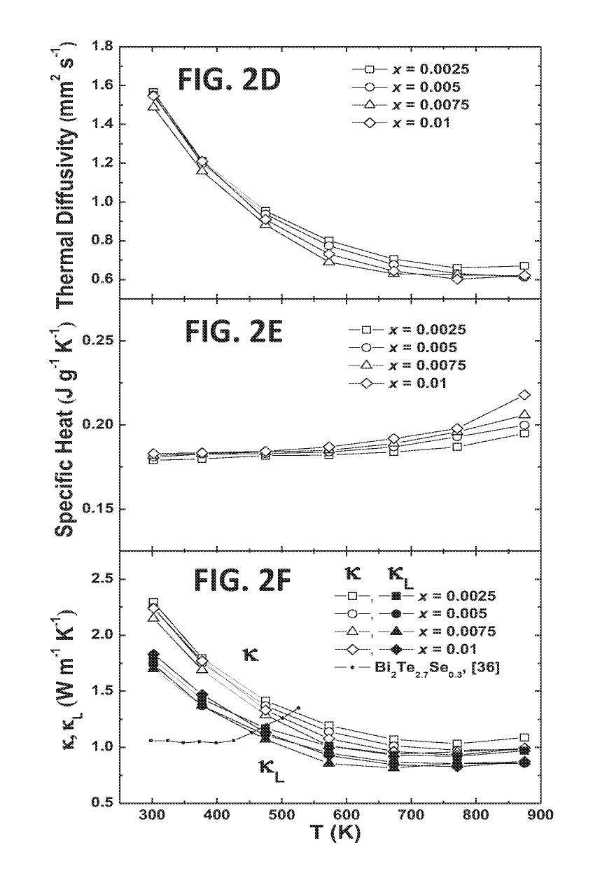

FIGS. 2A-2F illustrate the temperature dependence of a plurality of properties for thermoelectric materials fabricated according to embodiments of the present disclosure. In particular, FIGS. 2A-2F illustrate the temperature dependence of electrical conductivity (FIG. 2A), Seebeck coefficient (FIG. 2B), power factor (FIG. 2C), thermal diffusivity (FIG. 2D), specific heat (FIG. 2E), total thermal conductivity (κₜₒₜₐₗ) and lattice thermal conductivity (κ_{L}) (FIG. 2F) for Pb₁₋ₓCrₓSe (x=0.0025, 0.005, 0.0075, and 0.01) as compared with certain reported data on n-type Bi₂Te_{2.7}Se_{0.3}. All the samples show metallic transport behavior. The electrical conductivity (FIG. 2A) of the TE materials fabricated according to embodiments of the present disclosure is higher than Bi₂Te_{2.7}Se_{0.3}, and the Seebeck coefficient (FIG. 2B) of those TE materials is comparable with Bi₂Te_{2.7}Se_{0.3} below 473 K. The room temperature power factor (FIG. 2C) reaches about 3.0×10⁻³ W m⁻¹ K⁻² for the fabricated TE materials, which is higher than certain reported doped PbSe and even Bi₂Te_{2.7}Se_{0.3}. PbSe has been shown to have lower lattice thermal conductivity (FIG. 2F) than PbTe, which may be attributed to the higher degree of anhamonicity of lattice vibrations in Pb Se. The lattice thermal conductivity of Cr-doped Pb Se was calculated by subtracting the charge carrier thermal conductivity from total thermal conductivity (κ_{L}=κₜₒₜₐₗ−κₑ=κₜₒₜₐₗ−L□T, where L is the Lorenz number calculated using a two-band model) and is illustrated in FIG. 2F. FIGS. 2D and 2E illustrate the thermal diffusivity and the specific heat of the samples.

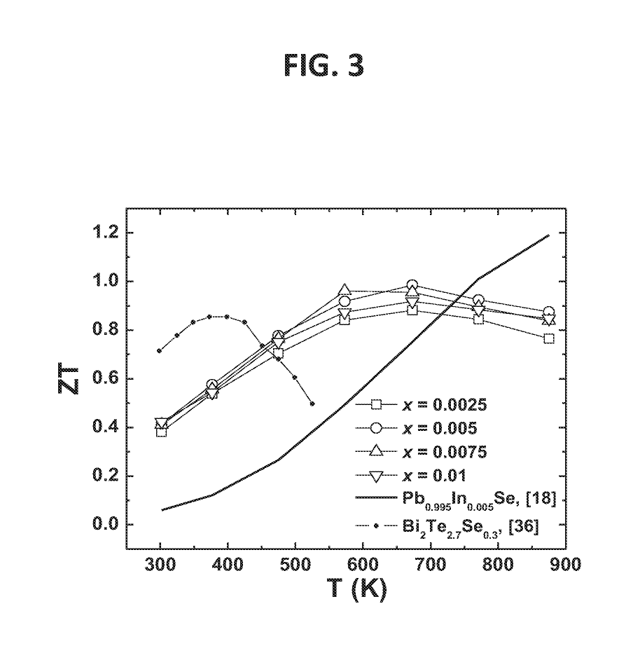

FIG. 3 illustrates the temperature dependence of thermoelectric materials according to certain embodiments of the present disclosure. FIG. 3 illustrates the temperature dependence of ZT for Pb₁₋ₓCrₓSe (x=0.0025, 0.005, 0.0075, and 0.01) in comparison with reported data on Bi₂Te_{2.7}Se_{0.3} by Yan et al.³⁶ (small solid circles) and reference data on In-doped PbSe (black line). As shown in FIG. 3, when the lattice thermal conductivity is combined with this relatively lower thermal conductivity, the room temperature ZT reaches about 0.4, which is higher than the reported data for In-doped n-type PbSe, although it is still lower than the room temperature ZT of Bi₂Te_{2.7}Se_{0.3}. The ZT values continuously increase and reach about 1.0 at about 573 K for Pb_{0.9925}Cr_{0.0075}Se and about 673 K for Pb_{0.995}Cr_{0.005}Se and stay above 0.9 from about 573 K to about 873 K, which strongly increases the average ZT of the PbSe-based materials, as will be discussed later. In subsequent experiments, following the method outlined above for Cr-doped PbSe, other transition metals close to Cr (in the periodic table of elements) including titanium (Ti), vanadium (V), chromium (Cr), niobium (Nb), and molybdenum (Mo), were used as dopants for PbSe.

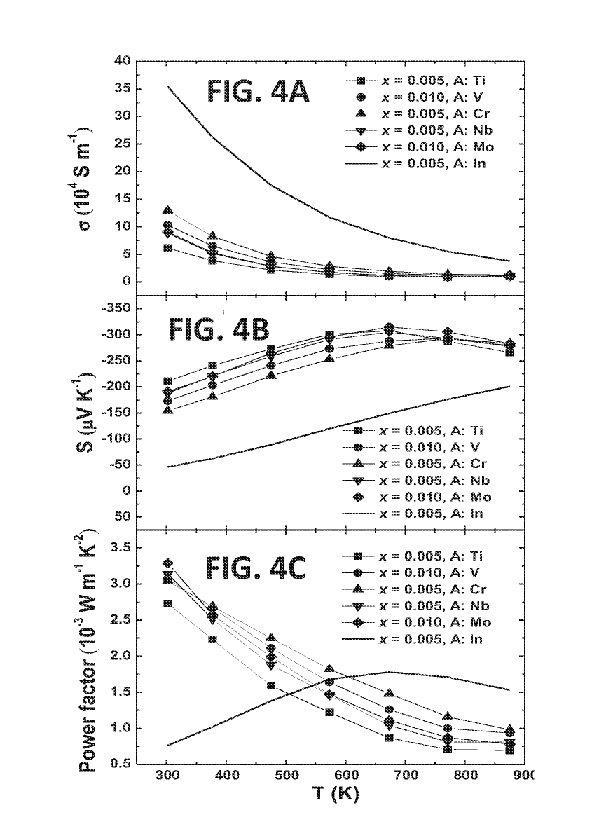

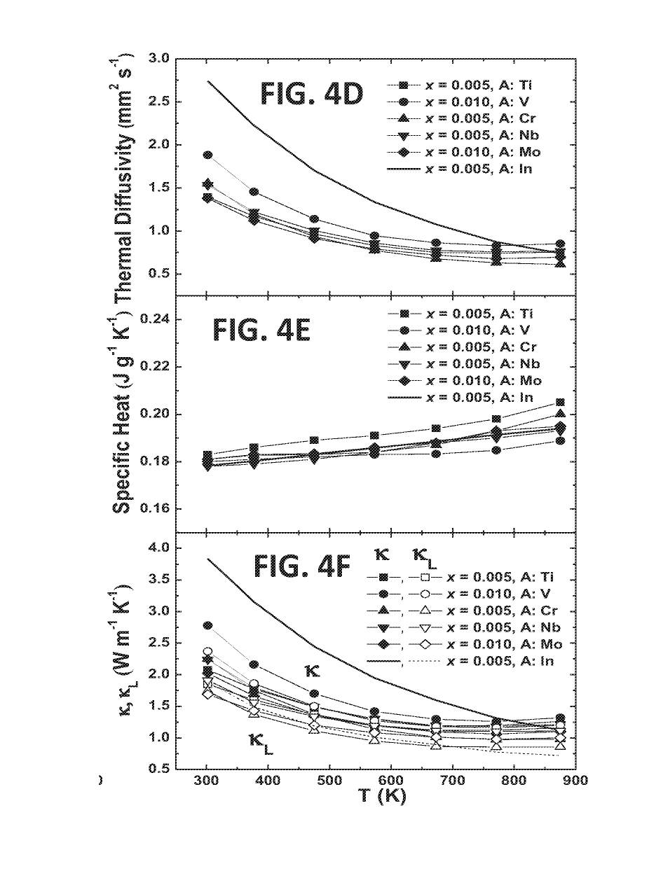

FIG. 4A-4F illustrate the temperature dependence of properties of thermoelectric materials fabricated according to certain embodiments of the present disclosure. The temperature dependence of the electrical conductivity (FIG. 4A), Seebeck coefficient (FIG. 4B), power factor (FIG. 4C), thermal diffusivity (FIG. 4D), specific heat (FIG. 4E), total thermal conductivity and lattice thermal conductivity (FIG. 4F) for optimized Pb₁₋ₓAₓSe (A: Ti, V, Cr, Nb, and Mo) (x=0.005 or 0.01) in comparison with certain reported data on In-doped PbSe (solid line) are illustrated. The samples still show the typical behavior of degenerate semiconductors. The electrical conductivity of the transition metal-doped PbSe is lower and the Seebeck coefficient is good across the whole temperature range (300-873 K). The power factor decreased with increasing temperature. The highest room temperature power factor is about 3.3×10⁻³ W m⁻¹ K⁻² for 1 at. % Mo-doped PbSe. Because of the lower electrical thermal conductivity, the total thermal conductivity is also lower compared with In-doped PbSe.

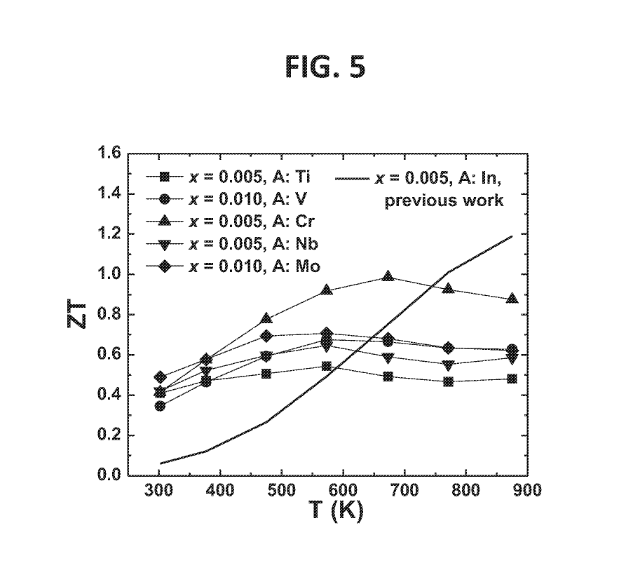

FIG. 5 illustrates ZT values for thermoelectric materials fabricated according to certain embodiments of the present disclosure. While FIGS. 4C and 4F illustrate that samples doped with 0.005 or 0.010 of Ti, V, Cr, Nb, and Mo, have a lower thermal conductivity and a higher power factor at lower temperatures. FIG. 5 illustrates that the ZT values of the samples from FIGS. 4A-4F are higher than In-doped PbSe below 600 K. The highest room temperature ZT is about 0.5 for 1 at. % Mo-doped PbSe and the highest peak ZT is about 1.0 for 0.5 at. % Cr-doped PbSe at about 673 K.

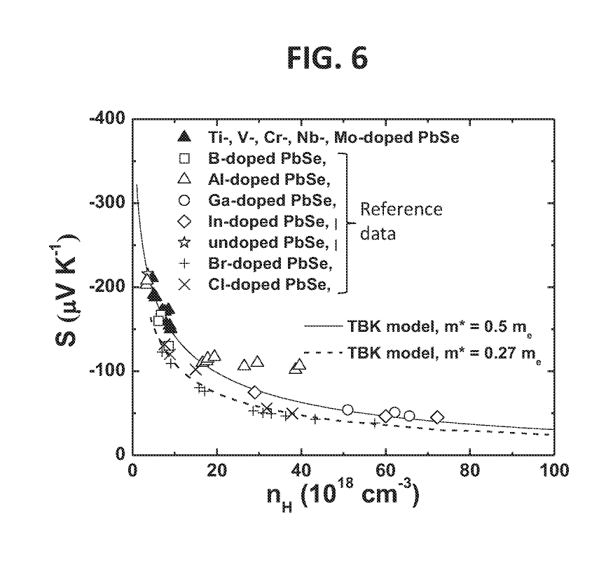

FIG. 6 illustrates the room temperature Pisarenko relations for the thermoelectric materials fabricated according to embodiments of the present disclosure. In FIG. 6, the room temperature Pisarenko relations for Pb₁₋ₓAₓSe (A: Ti, V, Nb, and Mo) (x=0.005 or 0.01) and Pb₁₋ₓCrₓSe (x=0.0025, 0.005, 0.0075, and 0.01) (filled triangles) from FIG. 4B are summarized and compared to certain reported n-type PbSe. The solid triangles represent the current work, and the other symbols indicate reference data from

Considering the nonparabolicity of the conduction band of PbSe, a two-band Kane (TBK) model was used to fit the data. The Cl- and Br-doped PbSe are fitted well with an effective mass of m*=0.27 mₑ (dashed line) and B-, Ga- and In-doped PbSe with m*=0.5 mₑ (solid line). Due to the resonant scattering, Al-doped PbSe deviates from the fitting line, showing almost constant Seebeck coefficient with increasing carrier concentration. Similar with B-, Ga- and In-doped Pb Se, all the transition metal Ti-, V-, Cr-, Nb-, and Mo-doped PbSe fell onto the fitting line with effective mass m*=0.5 mₑ. In spite of the formed deep resonant level in Cr-doped Pb Se, there is no effect of resonant scattering at all, nor is there in any of the other (Ti, V, Nb and Mo) transition metal-doped PbSe materials. FIG. 6 further illustrates the Pisarenko plots for Pb₁₋ₓAₓSe (A: Ti, V, Nb, and Mo) (x=0.005 or 0.01) and Pb₁₋ₓCrₓSe (x=0.0025, 0.005, 0.0075, and 0.01) (filled triangles) in comparison with reported data on B-doped PbSe (open squares), Al-doped PbSe (open triangles), Ga-doped PbSe (open circles), In-doped PbSe (open diamonds) and undoped PbSe (open stars) in previous findings and Cl-doped PbSe (crosses) and Br-doped PbSe (pluses). The black curve in FIG. 6 is based on nonparabolic two-band Kane model (TBK) with the electron effective mass of PbSe m*=0.5 mₑ. The dashed curve in FIG. 6 is based on nonparabolic TBK with the electron effective mass of PbSe m*=0.27 mₑ.

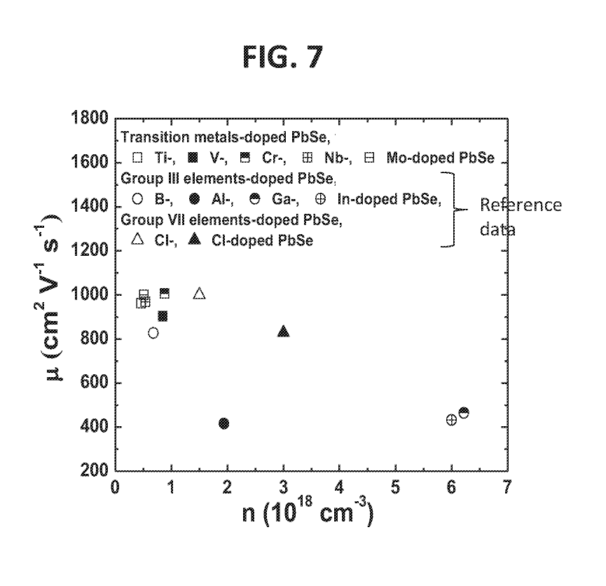

FIG. 7 illustrates the room temperature relationships of properties for thermoelectric materials fabricated according to embodiments of the present disclosure. FIG. 7 illustrates the room temperature relationships between μ and n for the optimal transition metal-doped PbSe, together with the reported n-type PbSe are shown in FIG. 7. In an embodiment, a higher Seebeck coefficient is mostly attributed to the lower carrier concentration (n), which is in the range of (4-10)×10¹⁸ cm⁻³. For comparison, the room temperature properties are listed for optimally n-type doped PbSe by Ti, V, Cr, Nb, and Mo; B, Al, Ga, and In; Cl and Br in Table 1a. The higher room temperature ZT is mainly related to the higher room temperature power factor (PF=S²n□q). Both the Seebeck coefficient (S) (FIG. 6) and Hall mobility (□□ (FIG. 7) (□□□is inversely proportional to Hall carrier concentration (n). With relatively low n, the transition metal-doped PbSe has both higher S and □□contributing to the higher power factor at room temperature. In an embodiment, the optimal Hall carrier concentration is from about 10¹⁸- to about 10¹⁹ cm⁻³ for a good/useful ZT at room temperature for Cr-doped PbSe, so, by balancing the Hall carrier concentration, a higher, preferred ZT may be possible. As used below, “˜” indicates that a measurement is “about” the stated value.

TABLE 1a
Comparison of room temperature properties for optimally doped n-type
PbSe using dopants Ti, V, Cr, Nb, Mo, B, Al, Ga, In, Cl, and Br.

| | Density | □ | S | PF | n | □ | □ | □_{L} | |
|---|---|---|---|---|---|---|---|---|---|
| | (g | (10⁴ S | (□V | (10⁻³ W | (10¹⁹ | (cm² | (W m⁻¹ | (W m⁻¹ | |
| Comp. | cm⁻³) | m⁻¹) | K⁻¹) | m⁻¹ K⁻²) | cm⁻³) | V⁻¹ s⁻¹) | K⁻¹) | K⁻¹) | ZT |
| Pb_{0.995}Ti_{0.005}Se | 8.14 | 6.13 | −211 | 2.73 | 0.46 | 962 | 2.077 | 1.85 | 0.41 |
| Pb_{0.99}V_{0.01}Se | 8.20 | 10.3 | −173 | 3.07 | 0.85 | 904 | 2.078 | 2.37 | 0.35 |
| Pb_{0.995}Cr_{0.005}Se | 8.05 | 12.9 | −154 | 3.04 | 0.88 | 1006 | 2.247 | 1.74 | 0.42 |
| Pb_{0.995}Nb_{0.005}Se | 8.20 | 8.84 | −188 | 3.14 | 0.54 | 968 | 2.239 | 1.91 | 0.42 |
| Pb_{0.99}Mo_{0.01}Se | 8.10 | 9.05 | −191 | 3.29 | 0.51 | 1000 | 2.025 | 1.69 | 0.49 |
| Pb_{0.98}B_{0.02}Se | 7.87 | 8.72 | −167 | 2.42 | 0.68 | 827 | 2.119 | 1.79 | 0.34 |
| Pb_{0.99}Al_{0.01}Se | 7.90 | 12.9 | −117 | 1.17 | 1.94 | 416 | 2.280 | 1.34 | 0.23 |
| Pb_{0.995}Ga_{0.005}Se | 7.94 | 38.5 | −51 | 1 | 6.22 | 465 | 3.759 | 1.69 | 0.08 |
| Pb_{0.995}In_{0.005}Se | 7.9 | 35.4 | −46.4 | 0.76 | 6 | 433 | 3.838 | 1.86 | 0.06 |
| PbSe_{0.996}Cl_{0.004} | 8.02 | ~23 | ~−105 | ~2.53 | 1.5 | ~1000 | ~2.67 | ~1.9 | ~0.27 |
| Pb_{1.002}Se_{0.9982}Br_{0.0018} | >8.1 | ~48.6 | −52 | ~1.31 | 3 | ~828 | ~3.38 | ~1.28 | ~0.11 |

Table 1b below provides the lattice parameters and the densities of Pb₁₋ₓCrₓSe (x=0.0025, 0.005, 0.0075, and 0.01).

| Nominal composition | Pb_{0.9975}Cr_{0.0025}Se | Pb_{0.995}Cr_{0.005}Se | Pb_{0.9925}Cr_{0.0075}Se | Pb_{0.99}Cr_{0.01}Se |
|---|---|---|---|---|
| Lattice parameter (Å) | 6.126 | 6.122 | 6.118 | 6.112 |
| Density (g cm⁻³) | 8.1 | 8.05 | 7.98 | 8 |

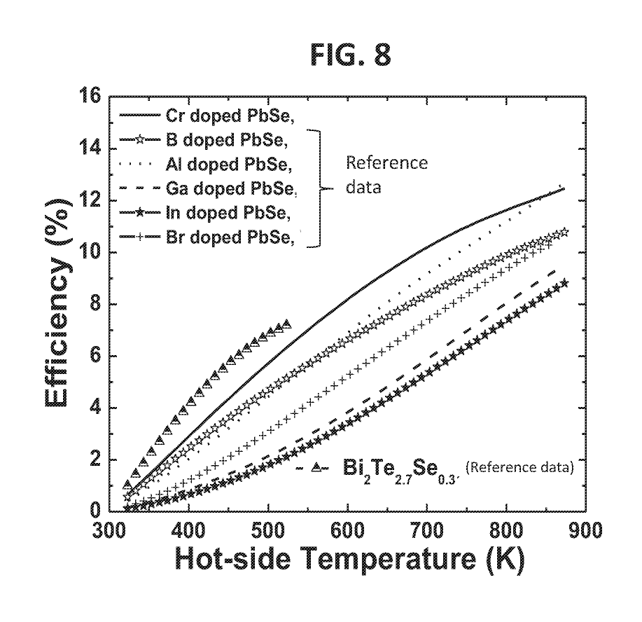

FIG. 8 illustrates the temperature dependence of device efficiency for thermoelectric materials fabricated according to certain embodiments of the present disclosure as compared to other materials. FIG. 8 illustrates the temperature dependence of device efficiency for 0.5 at. % Cr doped PbSe (red) in comparison with reported data for the optimized B-doped PbSe (green), Al-doped PbSe (pink), Ga-doped PbSe (blue), In-doped PbSe (light blue), Br-doped PbSe (purple), and Bi₂Te_{2.7}Se_{0.3} (dashed orange) with cold side temperature 300 K.

The discretization method of Mahan was used to estimate the device efficiency of the legs made by some of the n-type PbSe (solid lines) and n-type Bi₂Te_{2.7}Se_{0.3} (dashed line) with the cold side temperature at 300 K. The heat flow in the leg was assumed to be one-dimensional, neglecting losses from the side walls of the leg. The results are shown in FIG. 8. Cr-doped PbSe has the highest efficiency for a wide range of hot-side temperatures (350-873 K), even though higher peak ZTs are achieved in other n-type PbSe materials (1.3 at 850 K for Al doped PbSe, 1.2 at 850 K for Br-doped PbSe, and 1.2 at 873 K for Ga-, In-doped PbSe compared to only 1.0 at 673 K for Cr-doped PbSe). At the lower temperature range, when the hot side temperature is between 350 K and 523 K, the device efficiency of Cr-doped PbSe is only slightly lower than that of the temperature-limited n-type Bi₂Te_{2.7}Se_{0.3}. At high hot-side temperatures, the efficiency of Cr-doped PbSe is only rivaled by Al-doped PbSe, which may in some embodiments have a lower efficiency at lower hot-side temperatures. These results emphasize the benefits of a flatter ZT curve: not only is the efficiency higher at high temperatures, but also the efficiency is higher over a wide range of hot-side temperatures (from at least about 300K to about 900K).

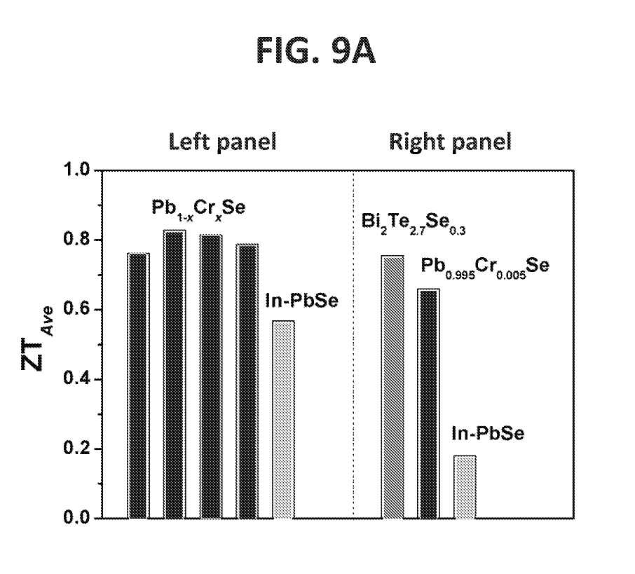

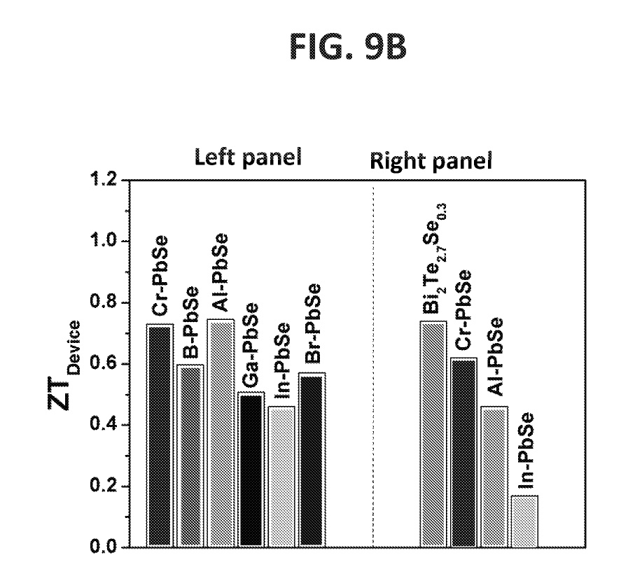

FIGS. 9A and 9B illustrate average ZT values for the thermoelectric materials fabricated according to certain embodiments of the present disclosure. Average ZTs (integrating of the area below the ZT curves) are presented in FIG. 9A (LEFT PANEL) from 300 to 873 K and device ZTs (obtained from the theoretically calculated power efficiency) are presented in FIG. 9B (LEFT PANEL) for devices operated between 300 K and 873 K for some of the n-type PbSe materials fabricated according to certain embodiments of the present disclosure.

FIG. 9A (RIGHT PANEL) illustrates the average ZTs between 300 K and 523 K for some n-type PbSe materials compared with FIG. 9B (RIGHT PANEL) which illustrates the device ZTs operated between 300 K and 523 K for n-type Bi₂Te_{2.7}Se_{0.3} fabricated according to embodiments of the present disclosure. As illustrated in FIGS. 9A and 9B, the Cr-doped PbSe (indicated by 4 bars in FIG. 9A's LEFT PANEL, has both a preferred average ZT and a device ZT compared to the other n-type PbSe, especially when working between 300 K and 523 K, and Bi₂T_{2.7}Se_{0.3} may comprise an even higher ZT over the same temperature range. Furthermore, the device ZT of Cr-doped PbSe (between 300 K and 873 K, as shown in FIG. 5) is even higher than previously reported n-type PbTe:La/Ag₂Te (between 300 K and 775 K) which has a peak ZT of about 1.6 at 775 K. Many currently employed p-type PbTe materials, such as PbTe:Na (between 300 K and 750 K) with a peak ZT about 1.4 at about 750 K, PbTe:Tl (between 300 K and 775 K) with peak ZT about 1.4 at about 775 K, PbTe:Na/SrTe (between 300 K and 775 K) with peak ZT about 1.5 at about 775 K, and PbTe_{0.85}Se_{0.15}:Na (between 300 K and 800 K) with peak ZT about 1.8 at about 800 K, could benefit from a flatter ZT curve. Considering the cost of Se compared to Te, and the higher device efficiency and wider working temperature range of PbSe than PbTe, PbSe has the potential to replace PbTe for thermoelectric applications.

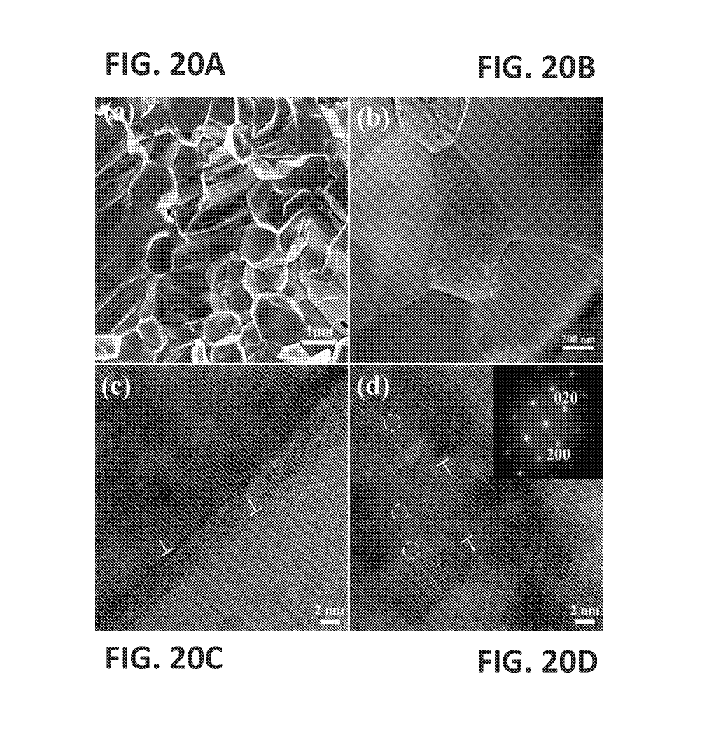

FIGS. 20A-20D are images of Pb_{0.995}Cr_{0.005}Se samples fabricated according to certain embodiments of the present disclosure. FIG. 20A is an SEM image, FIG. 20B is a low magnification TEM image, FIG. 20C is a HRTEM image, and FIG. 20D another HRTEM image. The sample of Pb_{0.995}Cr_{0.005}Se consists of both big grains with several to several tens of micrometers as shown in FIG. 20A, and small grains with several hundred nanometers as shown in FIG. 20B, and dislocations both on grain boundaries as shown in FIG. 20C (using the “T”) and on grain boundaries and within the grains (dotted circles) as illustrated in FIG. 20D. The inset in FIG. 2D is a selected area electron diffraction pattern from FIG. 2D. It is noted that the scale indications for these figures are: FIG. 20A, 1 μm; FIG. 20B, 200 nm; FIGS. 20C & 20D, 2 nm. These features, grain size, boundaries, etc., may contribute to the effective phonon scattering for the lower lattice thermal conductivity

As illustrated herein through the fabrication of thermoelectric materials according to certain embodiments of the present disclosure, transition metals including but not limited to Ti, V, Cr, Nb, and Mo can enhance the lower temperature (below 600 K) TE properties of n-type PbSe. Specifically, Cr doping in PbSe increases the room temperature ZT to about 0.4 and the peak ZT to about 1.0 between 573 K and 673 K, hence increasing the average ZT and efficiency of n-type PbSe over a wide temperature range (300 K to 873 K). This boost is not attributed to a resonant states effect. By further tuning the carrier concentration, improved properties can be expected. Cr-doped n-type Pb Se is believed to be promising for power generation applications.

PbTeSe-Based Thermoelectric Materials

Lead telluride and its alloys have been studied for medium temperature thermoelectric applications. However, little emphasis has been given to improve the figure-of-merit (ZT) near room temperature. Discussed herein are methods of fabrication of room temperature TE materials fabricated by Cr doping in PbTe_{1-y}Se_{y}, where y=0, 0.25, 0.5, 0.75, 0.85, and 1. The peak ZT temperature was found to increase with increasing concentration of Se. A ZT of about 0.6 at room temperature in Te-rich Cr_{0.015}Pb_{0.985}Te_{0.75}Se_{0.25} was obtained due to a lowered thermal conductivity and enhanced power factor resulted from high Seebeck coefficient of about −220 μV K⁻¹ and high Hall mobility of about 1120 cm² V⁻¹ s⁻¹ at room temperature. A room temperature ZT of about 0.5 and peak ZT of about 1 at about 573 K to 673 K is shown by Se-rich sample Cr_{0.01}Pb_{0.99}Te_{0.25}Se_{0.75}. This improvement of the room temperature ZT improved the average ZT over a wide temperature range and could potentially lead to a single leg efficiency of thermoelectric conversion for Te-rich Cr_{0.015}Pb_{0.985}Te_{0.75}Se_{0.25} up to about 11% and Se-rich Cr_{0.01}Pb_{0.99}Te_{0.25}Se_{0.75} up to about 13% with cold side and hot side temperature at 300 K and 873 K, respectively, if matched with appropriate p-type legs.

The thermoelectric performance of PbTe was enhanced as discussed herein by alloying with its isostructural sister compound PbSe. The partial substitution of Te by Se leads to disorder via atomic mass fluctuations, distortion in the crystal lattice and formation of defect states, which can effectively scatter phonons more than charge carriers (electrons or holes) to reduce thermal conductivity. Significant progress has been reported in improving the ZT of PbTe by simultaneous alloying, doping, and band engineering. Tl acts as a resonant dopant in PbTe to enhance the ZT to about 1.5 by modifying the band structure. By potassium doping, a peak ZT value of about 1.7 at 873 K was achieved in K_{0.02}Pb_{0.98}Te_{0.15}Se_{0.85}. A ZT of about 1.8 was obtained in p-type Na_{0.02}Pb_{0.98}Te_{0.85}Se_{0.15} by band convergence. Even though the peak ZTs of these materials at high temperatures are high, the average ZTs are low because the ZTs below 400 K are very low, which significantly reduces the efficiency of these materials.

In this systematic study of Cr doping in PbTe_{1-y}Se_{y}, a high figure of merit of about 0.6 at room temperature was achieved in Te-rich Cr_{0.015}Pb_{0.985}Te_{0.75}Se_{0.25} resulting from the combination of a higher power factor and a lower thermal conductivity. A peak ZT of about 1 was obtained in Se-rich Cr_{0.01}Pb_{0.99}Se_{0.75}Te_{0.25} at about 573 to 673 K with a room-temperature ZT of about 0.5. The calculated thermal to electrical conversion efficiencies of Te-rich Cr_{0.015}Pb_{0.985}Te_{0.75}Se_{0.25} and Se-rich Cr_{0.01}Pb_{0.99}Se_{0.75}Te_{0.25} are about 11% and about 13%, respectively, with hot side temperature of 873 K and cold side temperature of 300 K and hence could be potentially useful for medium temperature power generation applications.

Thermoelectric materials can directly convert heat into electricity without moving parts. The performance of a thermoelectric material is characterized by its dimensionless figure of merit (ZT), which is a function of materials' temperature-dependent properties, ZT=[S²□/(□ₑ+□_{L})]T, where S, σ, □ₑ, □_{L}, and T, are the Seebeck coefficient, electrical conductivity, electronic thermal conductivity, lattice thermal conductivity, and absolute temperature, respectively. Accordingly, making an efficient thermoelectric generator requires maximizing the dimensionless figure of merit over a wide temperature range, which ultimately demands materials with high Seebeck coefficients, high electrical conductivities, and low thermal conductivities. It is very difficult to independently tune these parameters since they are interrelated. Significant efforts have been put into decoupling them using various techniques. The introduction of nanostructures into bulk thermoelectric materials gives the opportunity to independently tune these parameters and significantly reduces the thermal conductivity by scattering a broad spectrum of phonons. Recently, band engineering based on modifying the band structure by alloying or doping to create impurity levels for resonating with the host band or both lead to significant achievements in obtaining higher ZT values.

Lead telluride (PbTe) with its intrinsically low thermal conductivity is one of the most studied thermoelectric materials for medium temperature applications. The thermoelectric performance of PbTe has been enhanced by alloying with its isostructural sister compound PbSe. The partial substitution of Te by Se leads to disorder via atomic mass fluctuations, distortion in the crystal lattice and formation of defect states, which can effectively scatter phonons more than charge carriers (electrons or holes) to reduce thermal conductivity. Significant progress has been reported in improving the ZT of PbTe by simultaneous alloying, doping, and band engineering. Tl acts as a resonant dopant in PbTe to enhance the ZT to about 1.5 by modifying the band structure. By potassium doping, a peak ZT value of about 1.7 at 873 K was achieved in K_{0.02}Pb_{0.98}Te_{0.15}Se_{0.85}. A ZT of about 1.8 was obtained in p-type Na_{0.02}Pb_{0.98}Te_{0.85}Se_{0.15} by band convergence. Even though the peak ZTs of these materials at high temperatures are high, the average ZTs are low because the ZTs below 400 K are very low, which significantly reduces the efficiency of these materials.

Cr was reported as a resonant donor in PbTe, PbSe, and PbTe_{1-y}Se_{y} systems at low temperatures. The room-temperature Seebeck coefficient and power factor in PbTe and Pb Se can be increased by Cr doping. However, the improvement was proved to not be due to resonant scattering. One study shows the formation of a Cr resonant state in PbTe, with an energy 100 meV above the conduction band bottom of PbTe at 0 K, but the state moves into the band gap when the temperature increases to room temperature and hence doesn't contribute to a power factor enhancement at or above room temperature. Another study also found Cr impurity states within the conduction band of PbTe. However, the band distortion that comes from such a resonance of the Cr impurity level is not broadened well enough to properly align the Fermi level with the enhanced density of states and hence doesn't contribute to the enhancement of Seebeck coefficient.

In this work, the enhancement of both the ZT near room temperature and the average ZT of PbTe_{1-y}Se_{y} across a wide temperature range with y=0, 0.25, 0.50, 0.75, 0.85, and 1 by Cr doping was studied. The reduction in thermal conductivity due to phonon scattering by the introduced point defects from the alloying, together with the optimized electronic properties by Cr doping, contributed to the enhancement of the room temperature ZT to about 0.6 for Te-rich Cr_{0.015}Pb_{0.985}Te_{0.75}Se_{0.25} and a peak ZT of about 1 at about 573 K to 673 K for Se-rich Cr_{0.01}Pb_{0.99}Te_{0.25}Se_{0.75} with a room temperature ZT of about 0.5. The calculated efficiency of each single leg Cr_{0.015}Pb_{0.985}Te_{0.75}Se_{0.25} and Cr_{0.01}Pb_{0.99}Te_{0.25}Se_{0.75} is about 11% and about 13%, respectively, with a cold side temperature of about 300 K and hot side temperature of about 873 K.

Thermoelectric Material Fabrication

Ingots of samples of CrₓPb₁₋ₓTe_{1-y}Se_{y} with x=0.005, 0.01, 0.015, and 0.02, and y=0, 0.25, 0.50, 0.75, 0.85, and 1 were prepared in a carbon coated quartz tube from high purity elements (Cr pieces, 99.99%; Pb granules, 99.99%; Te chunks 99.999%; Se granules, 99.99%) according to their stoichiometric weights. The tubes were evacuated to about 3×10⁻⁴ Pa and sealed, then slowly heated to 1000-1100° C. at a rate of 200° C./hour and then held at that temperature for 6 hours, then slowly cooled at the same rate to 650° C. and kept there for 50 hours, and then finally cooled to room temperature. The ingots obtained from this procedure were cleaned and hand milled in a glove box with an argon environment. The hand-milled powder was then loaded into a half inch graphite die, hot pressed at 600° C. for 2 minutes, air cooled, polished, cleaned, and cut to a desired shape for characterization.

Material Characterization

The microstructures were investigated by a scanning electron microscope (SEM, LEO 1525). Seebeck coefficient (S) and electrical conductivity (σ) measurements were done using a static direct current method and a four-point direct current switching method, respectively, on a commercial (ULVAC ZEM-3) system. The room-temperature Hall coefficient (R_{H}) was measured using a Quantum Design Physical Properties Measurement System. The Hall carrier concentration n_{H} and Hall mobility μ_{H} were calculated from the Hall coefficient R_{H} by n_{H}=(eR_{H})⁻¹ and μ_{H}=σR_{H}, respectively. The thermal diffusivity (σ) was measured by a laser flash analyzer (Netzsch LFA 457) and the specific heat (Cₚ) was measured on a differential scanning calorimetry thermal analyzer (Netzsch DSC 404° C.) whereas the volumetric density (D) was measured by the Archimedes method. The thermal conductivity was calculated by □=DαCₚ.

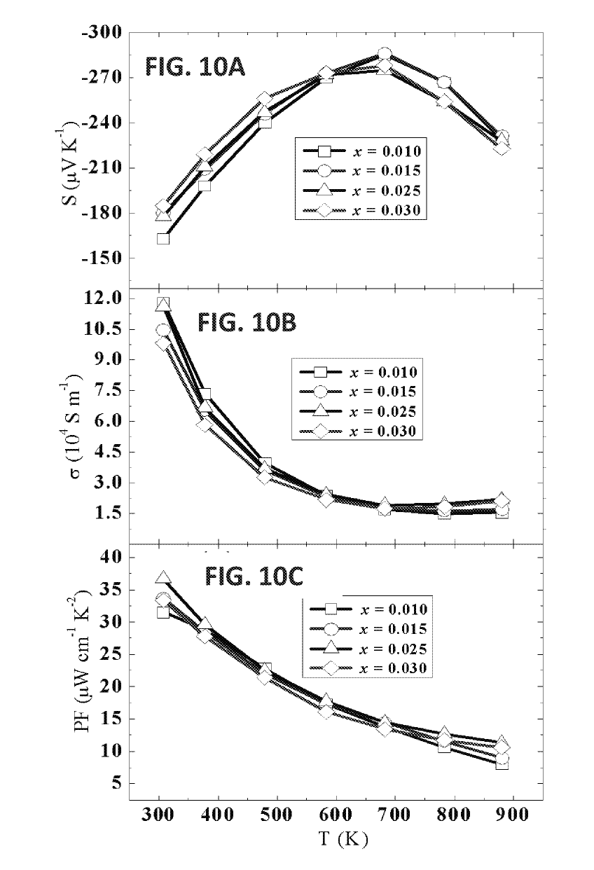

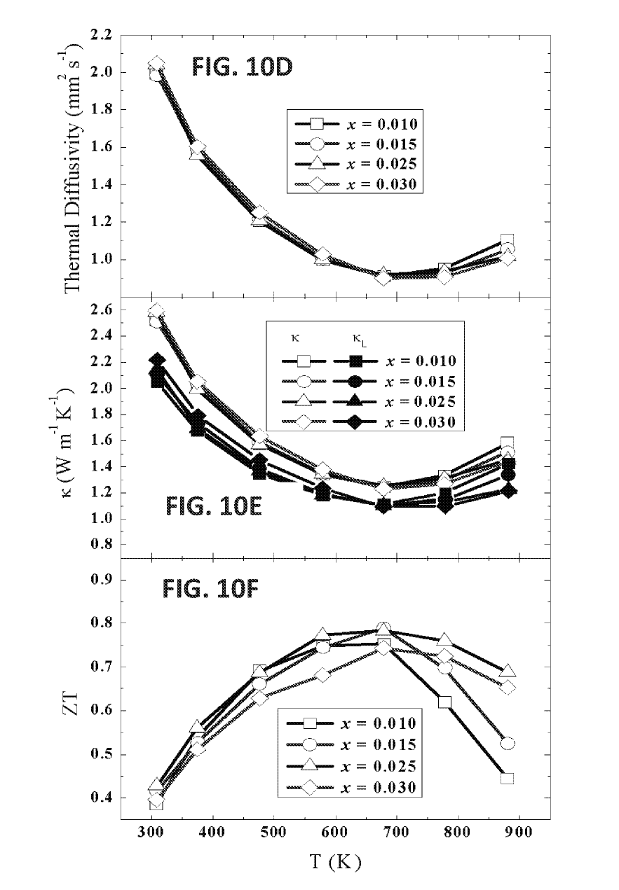

The lower thermal conductivity due to large Grüneisen parameter values and nanocomposite microstructures, and the improved power factor values by Cr doping have improved the average ZT of n-type PbSe over a wide temperature range (300 K-873 K). When Cr is doped into PbTe, the room temperature power factor increased dramatically compared with the other n-type PbTe alloys. The best power factor at room temperature is about 36.50 □W cm⁻¹ K⁻² in Cr_{0.025}Pb_{0.975}Te, which is approximately a 22% increase compared to Cr-doped PbSe. This result is close to values reported by B. Paul et al. on Cr-doped PbTe. However, the thermal conductivity increased to 2.6 W m⁻¹ K⁻¹ at room temperature and 1.3 W m⁻¹ K⁻¹ at 773 K, higher than those of Cr-doped PbSe (2.2 W m⁻¹ K⁻¹ at room temperature and 1.0 W m⁻¹ K⁻¹ at 773 K). FIG. 10 shows the temperature dependence of the thermoelectric properties of Cr-doped PbTe at various Cr concentrations. The calculated ZT is about 0.45 at room temperature and about 0.8 at 600 K to 773 K. The relatively lower thermal conductivity in PbSe and higher room temperature power factor from Cr doped PbTe motivated us to further optimize the alloy system by achieving the best power factor and lower thermal conductivity to achieve a higher room temperature ZT and average ZT.

FIGS. 10A-10F illustrate temperature-dependent thermoelectric properties of CrₓPb₁₋ₓTe manufactured according to certain embodiments of the present disclosure. Temperature-dependent thermoelectric properties of CrₓPb₁₋ₓTe at various dopant concentrations (x=0.01, 0.015, 0.025, and 0.03) are illustrated from about 300K to about 900K. In particular, FIG. 10A illustrates the Seebeck coefficient, FIG. 10B the electrical conductivity, FIG. 10C the power factor, FIG. 10D the thermal diffusivity, FIG. 10E the total thermal conductivity and lattice thermal conductivity, and FIG. 10F, the dimensionless figure-of-merit (ZT). The ZT is above about 0.5 for all of the samples from about 375 K to about 825K, and is at a peak for the x=0.015 and 0.025 samples at about 650K to about 700K.

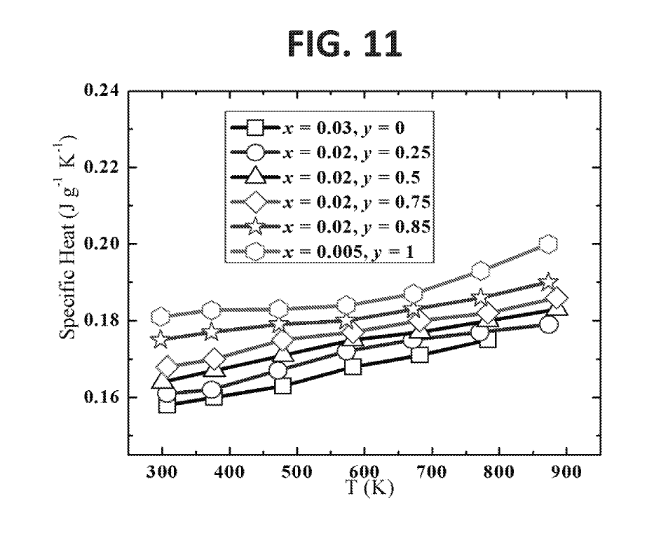

FIG. 11 illustrates the specific heat of thermoelectric materials fabricated according to certain embodiments of the present disclosure with varying concentrations of Cr, Pb, Te, and Se. FIG. 11 illustrates the temperature-dependent specific heat of CrₓPb₁₋ₓTe_{1-y}Se_{y} (x=0.005, 0.02, and 0.03, y=0, 0.25, 0.5, 0.75, 0.85, and 1). The Cₚ of the highest doping concentration (Cr_{0.03}Pb_{0.97}Te and Cr_{0.02}Pb_{0.98}Te_{1-y}Se_{y}) was used for the calculation of the total thermal conductivity for all the following studies. The lattice thermal conductivity is obtained by subtracting the electrical thermal conductivity (□ₑ=L□T, where L is the Lorenz number calculated using a two-band Kane model) from the total thermal conductivity. The specific heat was the highest for the x=0.005 and y=1 sample across the temperature range from about 300K to about 875K, and lowest for the x=0.03, y=0 sample.

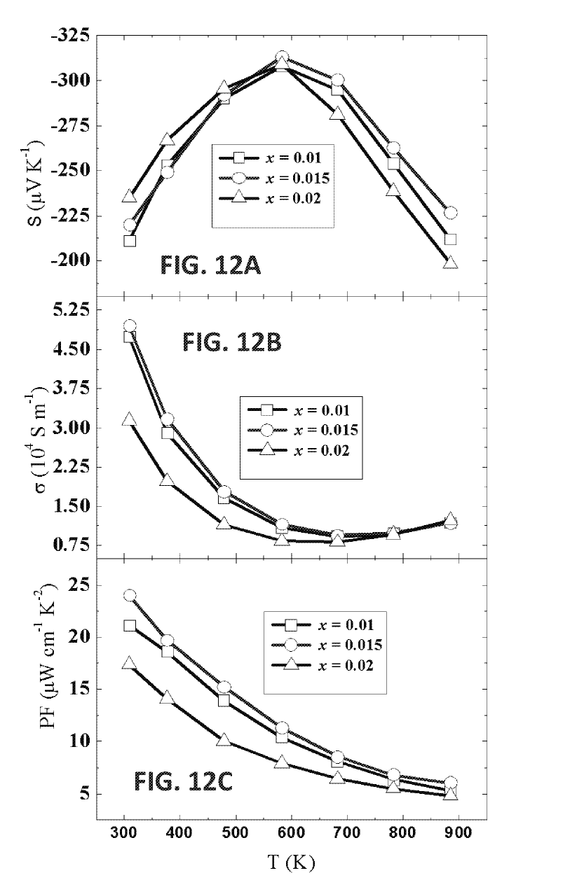

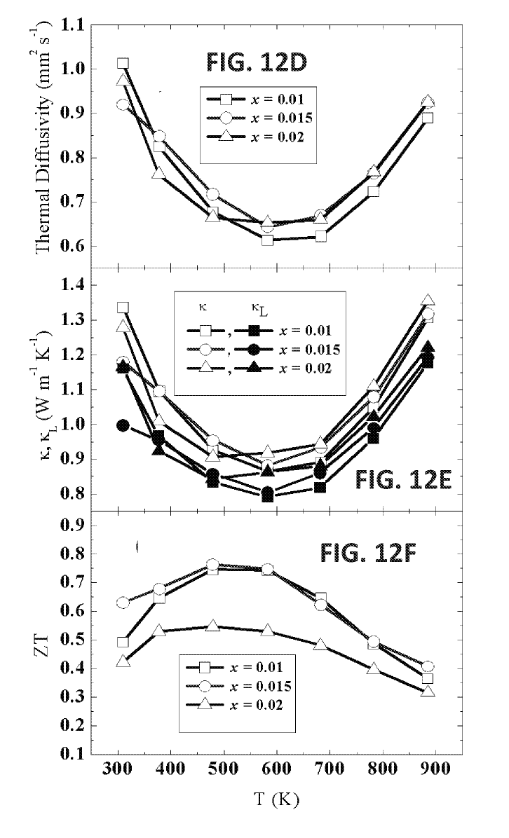

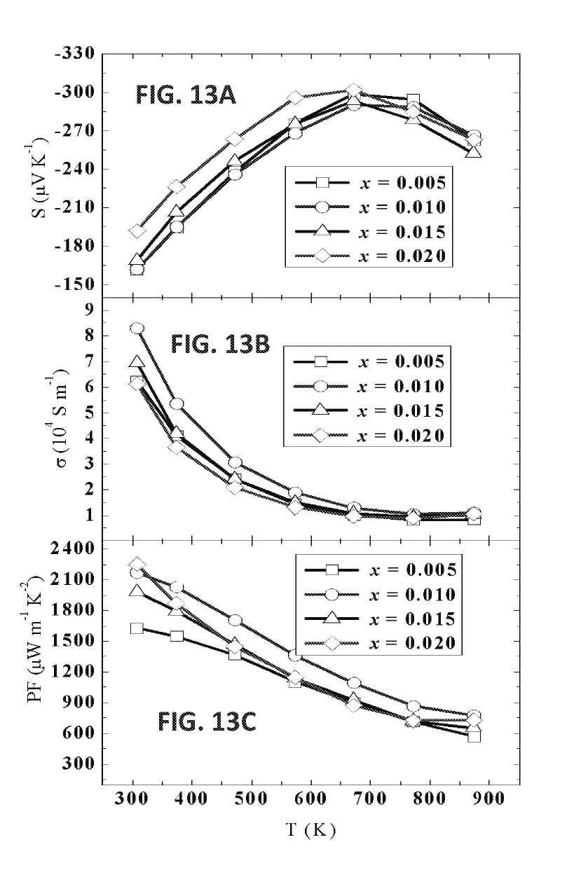

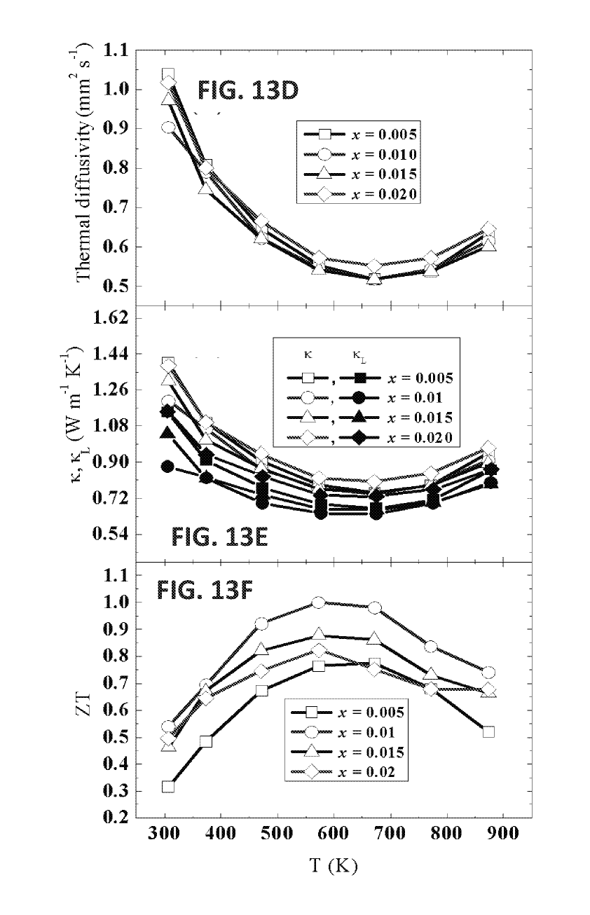

Different samples with compositions CrₓPb₁₋ₓTe_{0.75}Se_{0.25} and CrₓPb₁₋ₓTe_{0.25}Se_{0.75} were prepared and the temperature dependences of the thermoelectric properties are shown in FIGS. 12A-12F and 13A-13F and discussed below.

FIGS. 12A-12F illustrate temperature-dependent thermoelectric properties for thermoelectric materials fabricated according to certain embodiments of the present disclosure. FIGS. 12A-12F illustrate the temperature-dependence of thermoelectric properties of CrₓPb₁₋ₓTe_{0.75}Se_{0.25} (x=0.01, 0.015, and 0.02). Specifically, FIG. 12A shows the temperature dependence of the Seebeck coefficient, FIG. 12B shows the electrical conductivity, FIG. 12C illustrates the power factor, FIG. 12D illustrates the thermal diffusivity, FIG. 12E illustrates the total thermal conductivity and lattice thermal conductivity, and FIG. 12F shows the ZT.

For CrₓPb₁₋ₓTe_{0.75}Se_{0.25}, FIG. 12A illustrates that the Seebeck coefficient has a slight increase when the Cr doping level increases from 1 atm. % (0.01) to 2 atm. % (0.02) and a strong bipolar effect at elevated temperatures. The electrical conductivity (FIG. 12B) first increases when the Cr doping reaches a critical value of 1.5 atm. % and then decreases when the doping concentration of Cr increases to 2 atm. %. This is due to the reduction in the mobility of electrons with increasing defect density as the dopant contributes to disorder at higher concentrations. FIG. 12B shows a relatively higher electrical conductivity at a 1.5 atm. % Cr doping level, which is attributed to the higher carrier mobility (about 1120 cm² V⁻¹ s⁻¹) as confirmed by the room-temperature Hall measurement. This electrical conductivity in combination with the high Seebeck coefficient (FIG. 12A) yields a higher room-temperature power factor (FIG. 12C) of about 24 □W cm⁻¹ K⁻². The ZT, as illustrated in FIG. 12F, is above about 0.5 for all of the samples from about 400 K to about 600K, and is above 0.7 for the x=0.01 and the x=0.015 samples from about 400 K to about 600K.

FIGS. 13A-13F illustrate temperature-dependent thermoelectric properties for thermoelectric materials fabricated according to certain embodiments of the present disclosure. In particular, FIGS. 13A-13F illustrate the temperature-dependence of thermoelectric properties of CrₓPb₁₋ₓTe_{0.25}Se_{0.75} (x=0.005, 0.01, 0.015, and 0.02) including the Seebeck coefficient, (FIG. 13A), the electrical conductivity (FIG. 13B), the power factor (FIG. 13C), the thermal diffusivity (FIG. 13D), the total thermal conductivity (κ) and lattice thermal conductivity (κ_{L}) (FIG. 13E), and the ZT (FIG. 13F).

For CrₓPb₁₋ₓTe_{0.25}Se_{0.75}, as shown in FIG. 13A, the Seebeck coefficient shows a similar trend as the Te-rich (FIG. 12A) system with increasing Cr concentration. However, this composition is less susceptible to bipolar conduction and the bipolar temperature is higher than that of the Te-rich composition. This is due to the suppression of minority carriers by the band gap increase in the Se-rich composition with increasing temperature consistent with the previous studies. The electrical conductivity (FIG. 13B) also follows a similar trend as the Te-rich composition in such a way that it increased when the Cr concentration increased to a value of 1.5 atm. % then decreased when it exceeds this value. The lowest room temperature thermal conductivity (FIG. 13E) is about 1 and about 0.8 at about 673 K in Cr_{0.01}Pb_{0.99}Te_{0.25}Se_{0.75}, giving rise to a highest peak ZT (FIG. 13F) of about 1 at approximately 573 K to 673 K with a room temperature ZT of about 0.5.

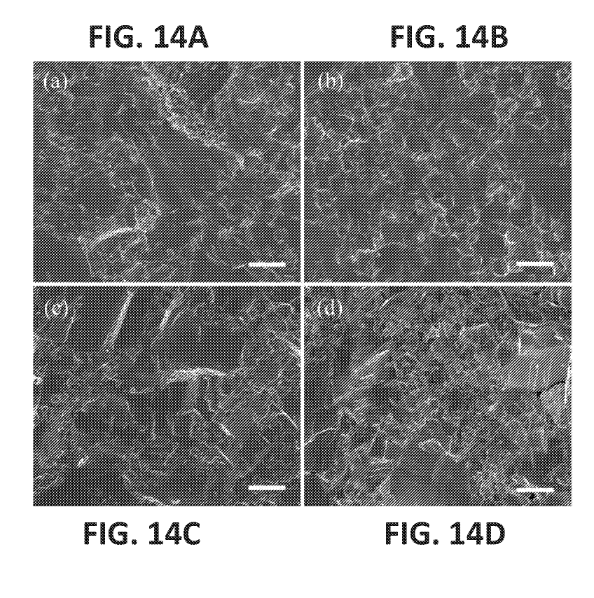

FIGS. 14A-14D are SEM images for varying thermoelectric compositions fabricated according to embodiments of the present disclosure. FIGS. 14A-14D illustrate SEM images for Cr_{0.025}Pb_{0.975}Te (FIG. 14A), Te-rich Cr_{0.015}Pb_{0.985}Te_{0.75}Se_{0.25} (FIG. 14B), Se-rich Cr_{0.01}Pb_{0.99}Te_{0.25}Se_{0.75} (FIG. 14C), and Cr_{0.005}Pb_{0.995}Se (FIG. 14D). The scale bar used for each image of FIGS. 14A-14D is 10 □m.

The thermal conductivity (FIG. 13E) is decreased due to the alloying effect and also may be due to the nanocomposite structure shown in FIGS. 14A-14D. All the CrₓPb₁₋ₓTe_{1-y}Se_{y} samples comprise of both big grains with diameters of several to several tens of microns (about 1 microns to about 20 microns) and small grains with several tens to hundreds of nanometers (about 50 nm to about 800 nm). The lattice thermal conductivity (FIG. 13E) of the samples is reduced by enhanced boundary scattering of the phonons. The lowest thermal conductivity (FIG. 13E) is about 0.9 W m⁻¹ K⁻¹ at about 573 K. However, there is a small influence on the room temperature value, which decreased and then increased when the Cr doping level varied from 1 atm. % to 2 atm. % showing a minimum value of about 1.2 W m⁻¹ K⁻¹ at a doping concentration of 1.5 atm. %, which leads to a ZT of about 0.6 in lead chalcogenide systems at room temperature. This ZT value (FIG. 13F) is lower than the ZT of previously fabricated Bi₂Te_{2.7}Se_{0.3}. The increase of the thermal conductivity at elevated temperatures is therefore due to the minority carriers.

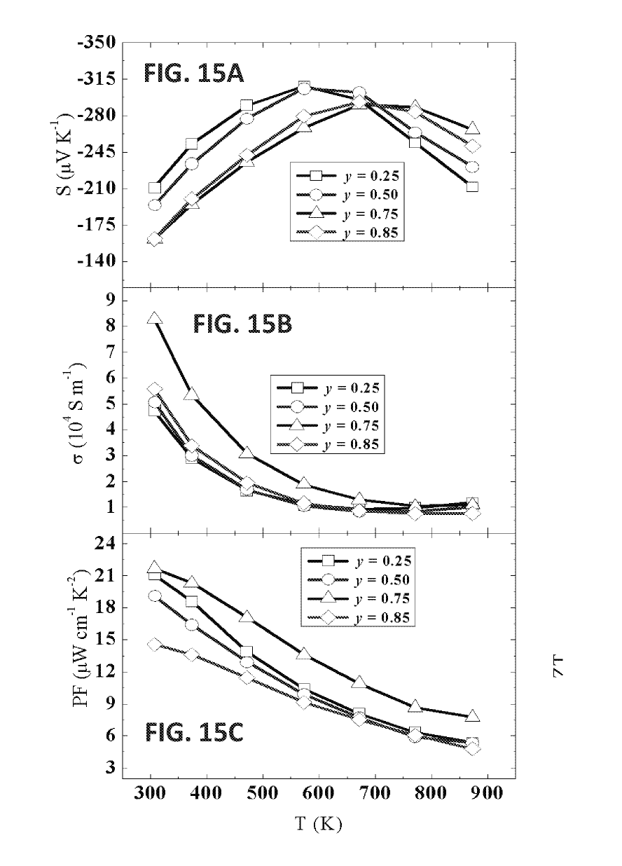

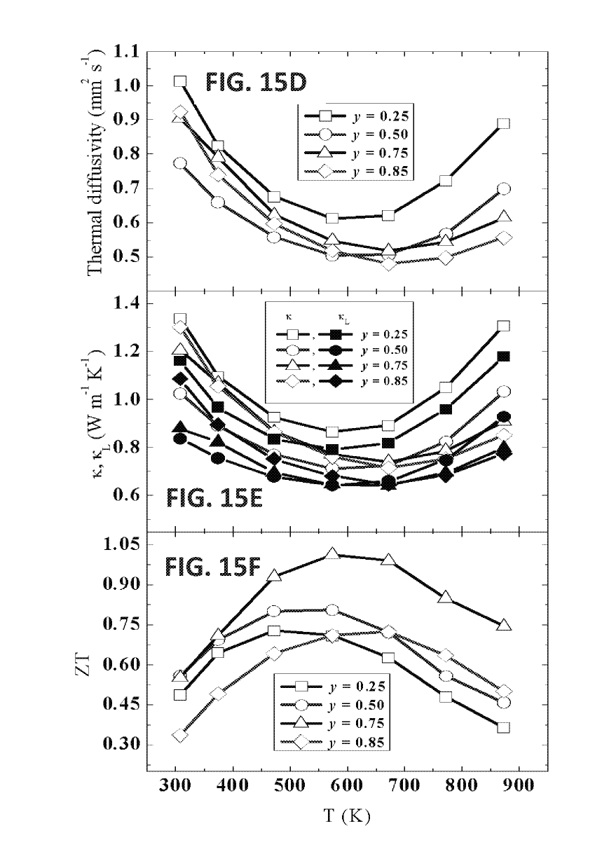

FIGS. 15A-15F illustrate the temperature dependence of properties of thermoelectric materials fabricated according to certain embodiments of the present disclosure. In particular, the temperature-dependence of thermoelectric properties of Cr_{0.01}Pb_{0.99}Te_{1-y}Se_{y} (y=0.25, 0.5, 0.75, 0.85) with fixed Cr concentration of 1 atm. % are illustrated in FIG. 15A (Seebeck coefficient), FIG. 15B (electrical conductivity), FIG. 15C (power factor), FIG. 15D (thermal diffusivity), FIG. 15E (total thermal conductivity and lattice thermal conductivity), and FIG. 15F (ZT).

Samples with different Se concentrations were fabricated to check the alloying effect. The electrical conductivity (FIG. 15B) of all the samples decreased with increasing temperature, consistent with the attributes of degenerate semiconductors. At fixed concentration of 1 atm. % Cr doping, the room-temperature Seebeck coefficient (FIG. 15A) decreased from −211 μV K⁻¹ to −157 μV K⁻¹ with increasing Se concentration. The Seebeck coefficient (FIG. 15A) of all the samples decreased at higher temperatures showing a bipolar transport nature and it was found that the temperature at which the bipolar effect becomes important for Te-rich samples is lower than that of Se-rich samples. The electrical conductivity (FIG. 15B) increased when the Se concentration increased to 75 atm. % and then decreased above this concentration showing a higher value at an optimum Se concentration of 75 atm. %. The high electrical conductivity manifested by the Se-rich sample Cr_{0.01}Pb_{0.99}Se_{0.75}Te_{0.25} resulted in a higher power factor across the whole temperature range. This high electrical conductivity is attributed to the relatively higher carrier concentration (about 8.12×10¹⁸ cm⁻³) as evidenced by the room-temperature Hall measurement.

The thermal conductivity (FIG. 15E) is heavily decreased compared to Cr doped PbTe and PbSe samples due to phonon scattering by the point defects resulting from alloying. A minimum thermal conductivity of about 0.8 W m⁻¹ K⁻¹ at 573 K was observed in Cr_{0.01}Pb_{0.99}Te_{0.5}Se_{0.5} with equal stoichiometry of Te and Se. This is approximately a 72% decrease compared to PbTe for the same Cr doping level of 1 atm. %. This reduction is related to the maximum distortion of the crystal lattice due to the maximum entropic atomic mass fluctuation as confirmed by theoretical calculations and experimental studies. The increase in thermal conductivity at higher temperatures is due to the contribution of heat transport by minority carriers (holes). The highest ZT (FIG. 15F) is about 1 at approximately 573 K to 673 K in Se-rich Cr_{0.01}Pb_{0.99}Te_{0.25}Se_{0.75}.

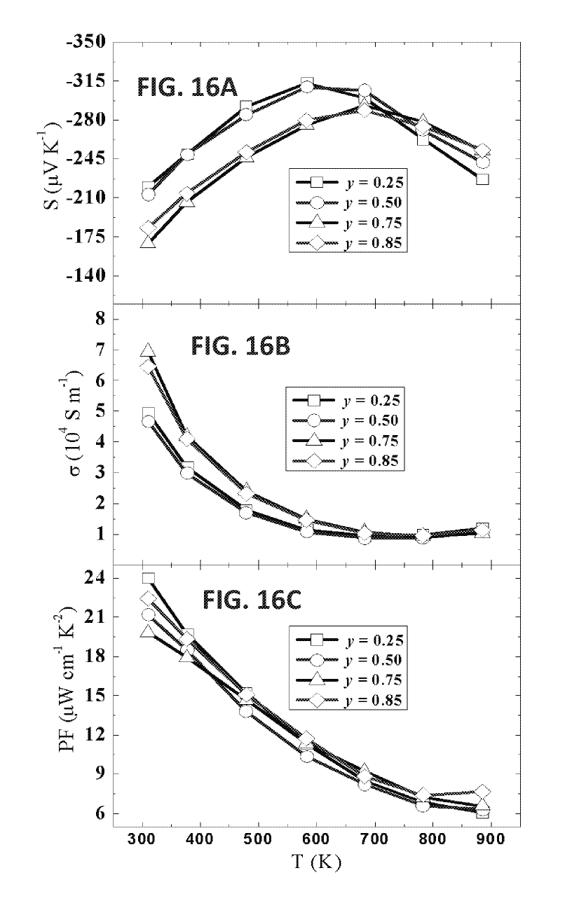

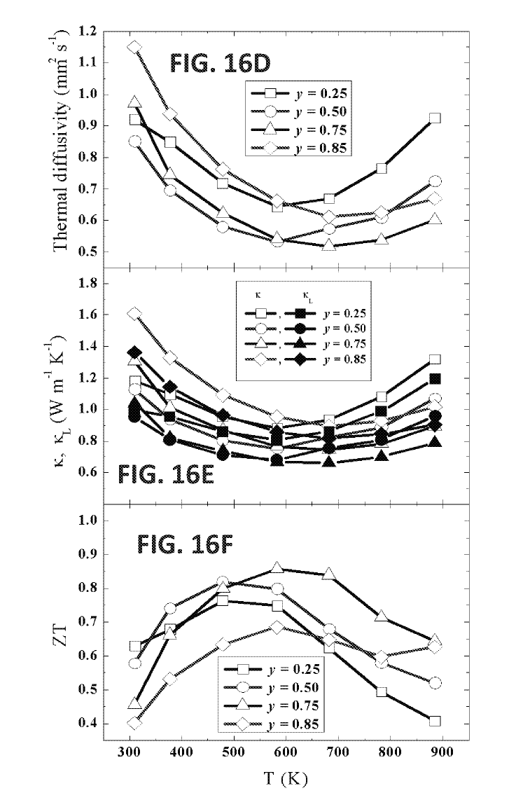

FIGS. 16A-16F illustrate temperature-dependent thermoelectric properties of thermoelectric materials fabricated according to certain embodiments of the present disclosure. Temperature-dependent thermoelectric properties of Cr_{0.015}Pb_{0.99}Te_{1-y}Se_{y} (y=0.25, 0.5, 0.75, 0.85) with fixed Cr concentration of 1.5 atm. % are illustrated, including the Seebeck coefficient (FIG. 16A), the electrical conductivity (FIG. 16B), the power factor (FIG. 16C), the thermal diffusivity (FIG. 16D), the total thermal conductivity and lattice thermal conductivity (FIG. 16E), and the ZT (FIG. 16F).

At a Cr doping concentration of 1.5 atm. % as shown in FIG. 16A, the Seebeck coefficient (FIG. 16A) follows a similar trend as in 1 atm. % Cr doping (FIG. 15A) with increasing Se concentration. FIG. 16A illustrates that the peak room-temperature Seebeck coefficient of −220 μV K⁻¹ was obtained in Te-rich Cr_{0.015}Pb_{0.985}Te_{0.75}Se_{0.25}. The electrical conductivity (FIG. 16B) increases when the Se concentration is higher than 50 atm. %. The minimum electrical conductivity is observed at equal stoichiometry of Te and Se because of the reduction in carrier mobility due to the maximum defect density. Se-rich samples show higher electrical conductivity (FIG. 16B) but the power factor (FIG. 16C) is not enhanced that much due to the lower Seebeck coefficient (FIG. 16A). A highest room temperature power factor (FIG. 16C) of about 24 □W cm⁻¹ K⁻² is shown by the Te-rich Cr_{0.015}Pb_{0.985}Se_{0.25}Te_{0.75}, which is due to the high value of the Seebeck coefficient (FIG. 16A) as discussed above. The thermal conductivity (FIG. 16E) is highly reduced due to the alloying effect. A room-temperature thermal conductivity (FIG. 16E) of about 1.2 W m⁻¹ K⁻¹ was obtained for the Te-rich sample Cr_{0.015}Pb_{0.985}Se_{0.25}Te_{0.75} and it is a 52% decrease compared to PbTe for the same 1.5 atm. % Cr doping level. Thus, by simultaneously reducing the thermal conductivity and enhancing the power factor, a peak ZT (FIG. 16F) of about 0.63 is obtained in Te-rich Cr_{0.015}Pb_{0.985}Te_{0.75}Se_{0.25} at room temperature.

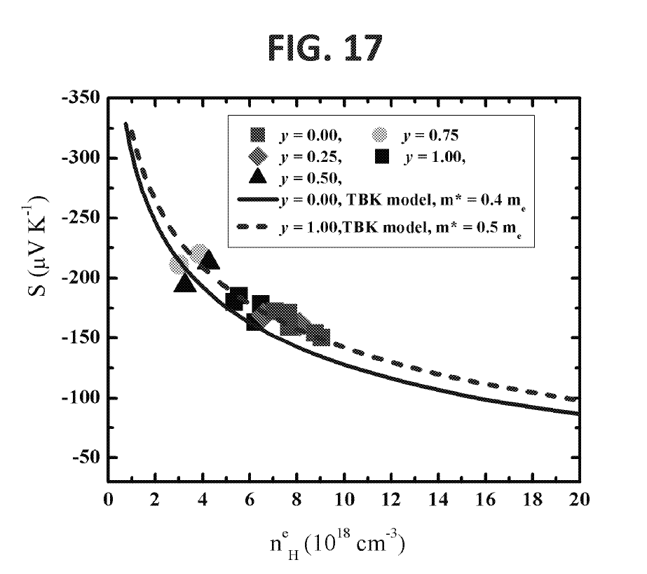

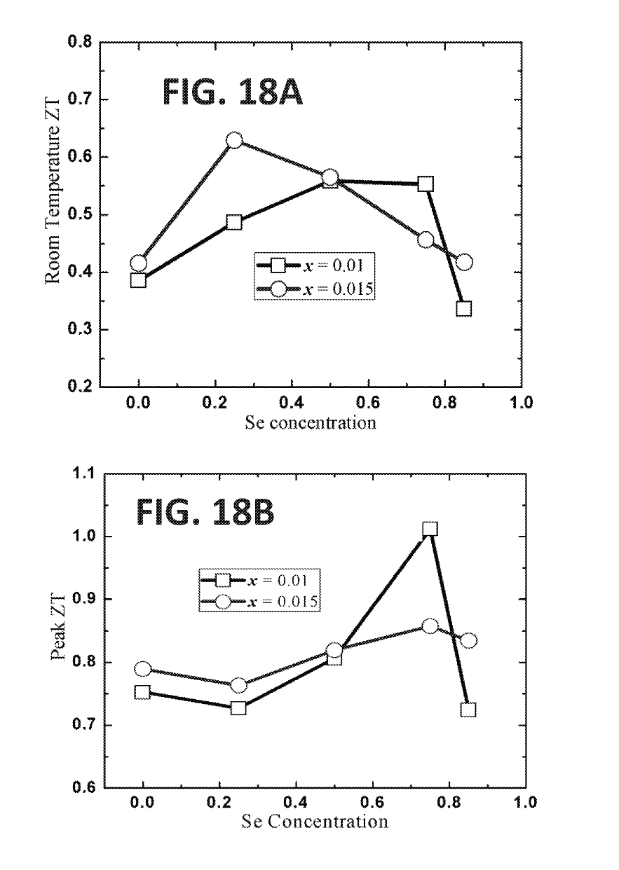

FIG. 17 is a graph of a plurality of Pisarenko plots of thermoelectric materials fabricated according to certain embodiments of the present disclosure. In order to see how Cr doping affected the band structure and influenced the Seebeck coefficient, the room temperature relationship between the Seebeck coefficient and the Hall carrier concentration of CrₓPb₁₋ₓTe_{1-y}Se_{y} is illustrated in FIG. 17. FIG. 17 illustrates room-temperature Pisarenko plots of CrₓPb₁₋ₓTe_{1-y}Se_{y}, (black squares) CrₓPb₁₋ₓTe (x=0.01, 0.015, 0.025, and 0.03), (green circles) CrₓPb₁₋ₓTe_{0.75}Se_{0.25} (x=0.01 and 0.015), (blue triangles) CrₓPb₁₋ₓTe_{0.5}Se_{0.5} (x=0.01 and 0.015), (teal diamonds) CrₓPb₁₋ₓTe_{0.25}Se_{0.75} (x=0.01 and 0.015), (pink squares) CrₓPb₁₋ₓSe (x=0.0025, 0.005, 0.0075, 0.01, and 0.02). The purple solid curve is based on a nonparabolic two-band Kane model (TBK) with the electron effective mass of PbTe m*=0.4 mₑ; the red dashed curve is based on a nonparabolic two-band Kane model (TBK) with the electron effective mass of PbSe m*=0.5 mₑ.

All the Hall carrier concentrations are lower than 1.0×10¹⁹ cm⁻³ and the absolute Seebeck coefficients are higher than 150 μV K⁻¹. The Hall carrier concentration is lower than that of the Cr doped PbTe if the Se concentration is low (y=0.25 and 0.5, Te-rich samples), and increases higher than that of Cr doped PbTe with higher Se concentration (y=0.75 and 1, Se-rich samples). With increasing Hall carrier concentration, the Seebeck coefficient decreases. This is fitted well by the non-parabolic two-band Kane (TBK) model of PbTe and PbSe where acoustic phonon scattering is considered as the dominant carrier scattering mechanisms in both cases, showing no indication of a resonant state contribution to the high room-temperature power factor.

Table 2 summarizes the room-temperature properties of the compositions Cr_{0.015}Pb_{0.985}Se_{0.25}Te_{0.75} and Cr_{0.01}Pb_{0.99}Se_{0.75}Te_{0.25} together. The density of both samples is close to their theoretical density and their carrier concentrations are less than 10¹⁹ cm⁻³.

TABLE 2
Room-temperature properties of best
optimized Se-rich Cr_{0.01}Pb_{0.99}Te_{0.25}Se_{0.75}
and Te-rich Cr_{0.015}Pb_{0.985}Te_{0.75}Se_{0.25} samples.

| | Density | S | □ | PF | □ | | n_{H} | μ_{H} |
|---|---|---|---|---|---|---|---|---|
| | (g | (μV | (10⁴ S | (□W cm⁻¹ | (W m⁻¹ | | (10¹⁸ | (cm² V⁻¹ |
| Comp. | cm⁻³) | K⁻¹) | m⁻¹) | K⁻²) | K⁻¹) | ZT | cm⁻³) | s⁻¹) |
| Cr_{0.01}Pb_{0.99}Te_{0.25}Se_{0.75} | 7.90 | −162 | 8.29 | 21.70 | 1.23 | 0.54 | 8.12 | 638 |
| Cr_{0.015}Pb_{0.985}Te_{0.75}Se_{0.25} | 8. | −220 | 6.94 | 24 | 1.17 | 0.63 | 3.87 | 1120 |

FIG. 18A illustrates the Se concentration dependence of the room temperature ZT and FIG. 18B illustrates the Se concentration dependence on the peak ZT for CrₓPb₁₋ₓTe_{1-y} Se_{y}. FIGS. 18A and 18B summarize the effect of Te substitutions by Se on the (FIG. 18A) room-temperature and (FIG. 18B) peak ZTs at fixed Cr doping levels of 1 atm. % (black squares) and 1.5 atm. % (red circles). As can be seen from the figure, the room-temperature ZT increased when the Se concentration increased up to a certain optimum alloying limit and then dropped when it exceeded this limit. High room-temperature ZTs of about 0.63 and about 0.55 were obtained by substitution of 25 atm. % and 75 atm. % Te by Se at Cr doping levels of 1.5 atm. % and 1 atm. %, respectively. As shown in FIGS. 15 and 16 at fixed Cr concentrations the best peak ZTs are in Se-rich samples. A maximum peak ZT of about 1 is obtained in Cr_{0.01}Pb_{0.99}Te_{0.25}Se_{0.75}. The peak ZTs of all the samples are greater than about 0.7 indicating that Cr doping on PbTe alloyed with Pb Se brings the best room-temperature thermoelectric properties without or with minimal reduction of the peak ZTs so that the average ZT is improved over the whole temperature range that makes the materials promising for power generation. The efficiency of thermal to electrical conversion of these selected compositions is discussed in the next section.

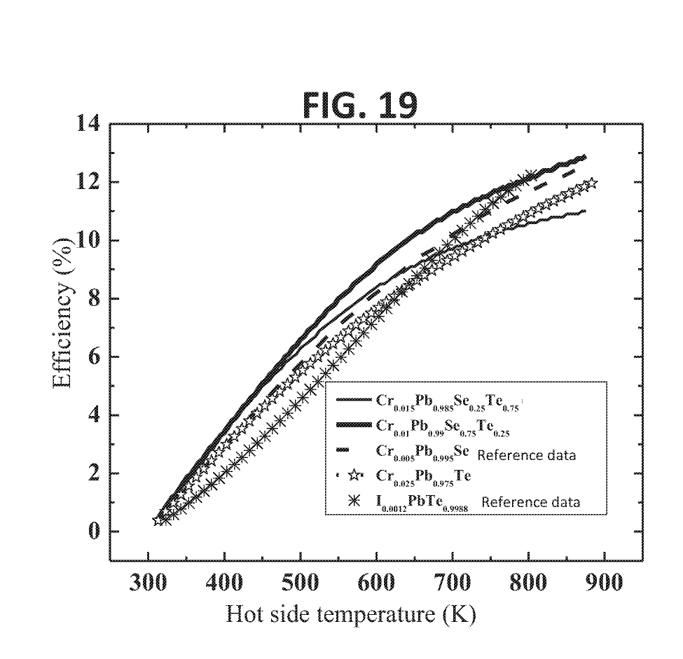

FIG. 19 illustrates the temperature dependence of the calculated leg efficiencies of thermoelectric materials fabricated according to certain embodiments of the present disclosure as compared to reference materials. In FIG. 19, the efficiency of thermoelectric materials including Cr_{0.015}Pb_{0.985}Te_{0.75}Se_{0.25} & Cr_{0.01}Pb_{0.99}Te_{0.25}Se_{0.75}, both fabricated according to embodiments of the present disclosure, Cr_{0.005}Pb_{0.995}Se (reference data) Cr_{0.025}Pb_{0.975}Te, fabricated according to embodiments of the present disclosure, and I_{0.0012}PbTe_{0.9988} (reference data) with a cold side temperature at 300 K.

The efficiency of a thermoelectric power generator depends on the Carnot efficiency and the thermoelectric figure-of-merit of the devices, which is intrinsic to the materials making up the device. This relation is expressed as

$${η}_{e} = \frac{{T}_{h} - {T}_{c}}{{T}_{h}} ( \frac{\sqrt{1 + Z \overline{T}} - 1}{\sqrt{1 + Z \overline{T}} + \frac{{T}_{c}}{{T}_{h}}} ) \qquad ( 1 )$$

where Tₕ is the hot-side temperature, T_{c} is the cold-side temperature, and T̅ is the average temperature between T_{c} and Tₕ. The temperature-dependent properties of the legs are incorporated in the ZT̅ term in Eq. 1 and replaced by the average ZT over the whole temperature range when calculating the efficiency. One proposed method of improving the efficiency of thermoelectric generators is designing a segmented device where each segment has a high ZT for the temperature anticipated in the segment. However, this technique has its own drawbacks in effectiveness since it suffers from the added complexity of bonding, mass diffusion, and thermal expansion mismatch at the interfaces. Hence, it is important to find a single material with better thermoelectric properties to use over the whole temperature range of operation. In an embodiment, Cr_{0.015}Pb_{0.985}Se_{0.25}Te_{0.75} and Cr_{0.01}Pb_{0.99}Se_{0.75}Te_{0.25} may be used for a single leg device application to operate from 300 K to 873 K. The leg efficiency can be calculated more accurately by either Snyder or Ursell or Mahan's discretization methods. Mahan's method was used herein where one dimensional heat flow is assumed in the legs and no heat is lost from the sidewalls. The discretized equations in the leg are given by

$$\begin{matrix}\frac{dT}{dx} = \frac{JST - Q}{k} & ( 2 ) \\ \frac{dQ}{dx} = ρ {J}^{2} + JS \frac{dT}{dx} & ( 3 ) \\ \frac{dV}{dx} = - ρ J - S \frac{dT}{dx} & ( 4 )\end{matrix}$$

where J, [symbol] , ρ, V, S, k and T are the current density, heat flux density, electrical resistivity, voltage, Seebeck coefficient, thermal conductivity, and temperature, respectively. The leg efficiency is calculated from the output power and input heat flux into the leg by:

$${η}_{leg} = \frac{J ( {V}_{c} - {V}_{h} )}{{Q}_{h}} \qquad ( 5 )$$

The set of coupled first order differential equations (2), (3), (4) were iteratively solved with the appropriate temperature boundary conditions at different current densities until the optimum value of J that maximizes the leg efficiency is found. The efficiency of Cr_{0.015}Pb_{0.985}Te_{0.75}Se_{0.25} and Cr_{0.01}Pb_{0.99}Te_{0.25}Se_{0.75} were calculated as shown in FIG. 19 in comparison with the efficiency of the best optimized Cr doped PbSe (Cr_{0.005}Pb_{0.995}Se), Cr doped PbTe (Cr_{0.025}Pb_{0.975}Te), and I doped PbTe (I_{0.0012}PbTe_{0.9988}). An efficiency of about 11% and about 13% was obtained for the individual legs of Cr_{0.015}Pb_{0.985}Te_{0.75}Se_{0.25} and Cr_{0.01}Pb_{0.99}Te_{0.25}Se_{0.75}, respectively, when the cold side temperature is set at 300 K and hot side temperature at 873 K. In spite of having high ZT exceeding 1.4 near 700 K for I_{0.0012}PbTe_{0.9988}, the efficiency is still lower than that of Cr_{0.01}Pb_{0.99}Te_{0.25}Se_{0.75}, especially below 700 K. This result is also comparable with the efficiency of other thermoelectric materials with cold side temperature 300 K and hot side temperature 773 K, for example Bi₂Te₃-Bi₂Se₃-Bi₂S₃ (12.5%), PbSe:Al (9.4%) half Heuslers (8.4%), filled Skutterrudites (13.1%), and PbTe:La (6.7%). This high single leg efficiency over a wide range of temperatures comes from the improvement of the room-temperature ZT and then the enhanced average ZT over the whole temperature range.

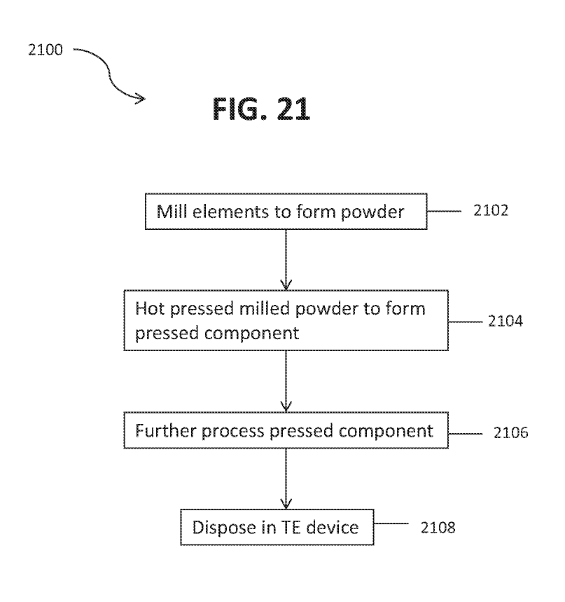

FIG. 21 is a flow chart of a method 2100 of fabricating thermoelectric materials and devices according to embodiments of the present disclosure. At block 2102, a plurality of components are ball-milled or hand-milled or otherwise processed to form a homogenous powder. The homogenous powder may comprise a plurality of particles with diameters equal to or less than about 10 micrometers. At block 2104, the milled powder is hot-pressed from 30 seconds to 5 minutes to forma pressed component. In some embodiments, the hot-pressing may be performed from between 300° C. to 600° C. The powder may comprise lead (Pb), selenium (Se), tellurium (Te), and a dopant (A) according to the formula according to the formula AₓPb₁₋ₓTe_{1-y}Se_{y}, where A comprises at least one of titanium (Ti), vanadium (V), chromium (Cr), niobium (Nb), and molybdenum (Mo). X and Y may be less than or equal to 0.05, and in some embodiments less than or equal to 0.02. In an embodiment, the thermoelectric material comprises a ZT above about 0.5 from about 300 K to about 780 K after hot-pressing. In some embodiments, at block 2106, the pressed component may be further processed thermally, mechanically, or thermo-mechanically before being disposed in a thermoelectric device at block 2108.

Where numerical ranges or limitations are expressly stated, such express ranges or limitations should be understood to include iterative ranges or limitations of like magnitude falling within the expressly stated ranges or limitations (e.g., from about 1 to about 10 includes, 2, 2.4, 2.8, 3, 3.1, 3.5, 4, etc.; greater than 0.10 includes 0.11, 0.12, 0.13, etc., and in some embodiments “about” may mean within a range such as +/−5% or +/−10%). For example, whenever a numerical range with a lower limit, Rₗ, and an upper limit, Rᵤ, is disclosed, any number falling within the range is specifically disclosed. In particular, the following numbers within the range are specifically disclosed: R=Rₗ+k*(Rᵤ−Rₗ), wherein k is a variable ranging from 1 percent to 100 percent with a 1 percent increment, i.e., k is 1 percent, 2 percent, 3 percent, 4 percent, 5 percent, . . . , 50 percent, 51 percent, 52 percent, . . . , 95 percent, 96 percent, 97 percent, 98 percent, 99 percent, or 100 percent. Moreover, any numerical range defined by two R numbers as defined in the above is also specifically disclosed. Use of broader terms such as “comprises,” “includes,” and “having” should be understood to provide support for narrower terms such as “consisting of,” “consisting essentially of,” and “comprised substantially of.” Each and every claim is incorporated into the specification as further disclosure, and the claims are exemplary embodiment(s) of the present invention.

While exemplary embodiments of the invention have been shown and described, modifications thereof can be made by one skilled in the art without departing from the scope or teachings herein. The embodiments described herein are exemplary only and are not limiting. Many variations and modifications of the compositions, systems, apparatus, and processes described herein are possible and are within the scope of the invention. Accordingly, the scope of protection is not limited to the embodiments described herein, but is only limited by the claims that follow, the scope of which shall include all equivalents of the subject matter of the claims. Unless expressly stated otherwise, the steps in a method claim may be performed in any order. The recitation of identifiers such as (a), (b), (c) or (1), (2), (3) before steps in a method claim are not intended to and do not specify a particular order to the steps, but rather are used to simplify subsequent reference to such steps.

1. A thermoelectric device comprising:
a thermoelectric material comprising:
lead (Pb);
selenium (Se);
and at least one other component A according to the formula Pb₁₋ₓAₓSe.

2. The thermoelectric device of claim 1, wherein A comprises at least one of titanium (Ti), vanadium (V), chromium (Cr), niobium (Nb), and molybdenum (Mo).

3. The thermoelectric device of claim 1, wherein x is greater than 0 and less than or equal to 0.02.

4. The thermoelectric device of claim 1, wherein the thermoelectric material is formed by hot-pressing and exhibits a ZT of greater than about 0.5 from about 300 K to about 900 K subsequent to the hot-pressing.

5. The thermoelectric device of claim 1, wherein the thermoelectric material is formed by hot-pressing and exhibits a ZT of greater than 1.0 from about 300 K to about 900 K subsequent to the hot-pressing.

6. A method of fabricating a thermoelectric material comprising:
hot-pressing a milled powder comprising lead (Pb), selenium (Se), tellurium (Te), and a dopant (A) according to the formula according to the formula AₓPb₁₋ₓTe_{1-y}Se_{y} to form a thermoelectric material, wherein the thermoelectric material comprises a ZT above about 0.5 from about 300 K to about 780 K.

7. The method of claim 6, wherein A comprises at least one of titanium (Ti), vanadium (V), chromium (Cr), niobium (Nb), and molybdenum (Mo).

8. The method of claim 6, wherein X is greater than 0 and less than or equal to 0.02.

9. The method of claim 6, wherein Y is greater than 0 and less than or equal to 0.02.

10. The method of claim 6, further comprising hot-pressing the milled powder for about 2 minutes.

11. The method of claim 6, further comprising hot-pressing the milled powder between 300° C. to 600° C.

12. The method of claim 6, wherein the milled powder comprises particle sizes of less than 10 micrometers in diameter.

13. A thermoelectric device comprising:
a thermoelectric material comprising:
lead (Pb);
tellurium (Te);
selenium (Se); and
a dopant A, according to the formula AₓPb₁₋ₓTe_{1-y}Se_{y}.

14. The thermoelectric device of claim 13, wherein A comprises at least one of titanium (Ti), vanadium (V), chromium (Cr), niobium (Nb), and molybdenum (Mo).

15. The thermoelectric device of claim 13, wherein X is less than or equal to 0.02.

16. The thermoelectric device of claim 13, wherein Y is less than or equal to 0.02.

17. The thermoelectric device of claim 13, wherein the thermoelectric material comprises a ZT above about 1.0 at about 300 K.

18. The thermoelectric device of claim 13, wherein the thermoelectric material comprises a ZT above 0.5 at about 300 K.

19. The thermoelectric device of claim 13, wherein the thermoelectric device comprises an efficiency of about 12.5%.

20. The thermoelectric device of claim 13, wherein the thermoelectric material comprises a ZT above about 0.5 from about 300 K to about 780 K.
